(19) United States
(12) Patent Application Publication
(10) Pub. No.: US 2025/0089237 A1
(43) Pub. Date: Mar. 13, 2025

(54) SEMICONDUCTOR DEVICE AND SEMICONDUCTOR MEMORY DEVICE

(71) Applicant: Kioxia Corporation, Tokyo (JP)

(72) Inventors: Takeru MAEDA, Yokkaichi Mie (JP); Shosuke FUJII, Kuwana Mie (JP); Kotaro NODA, Yokkaichi Mie (JP)

(73) Assignee: Kioxia Corporation, Tokyo (JP)

(21) Appl. No.: 18/595,558

(22) Filed: Mar. 5, 2024

(30) Foreign Application Priority Data
Sep. 13, 2023 (JP) 2023-148695

(51) Int. Cl. H10B 12/00

(52) U.S. Cl. CPC H10B 12/33; H10B 12/05

(57) ABSTRACT

A semiconductor device includes: an oxide semiconductor including a first end and a second end and extending in a first direction oriented from the second end to the first end; a first electrode configured to come into contact with the first end of the oxide semiconductor; a second electrode configured to come into contact with the second end of the oxide semiconductor; a gate electrode configured to enclose the oxide semiconductor with a first insulating film interposed therebetween between the first and second ends of the oxide semiconductor; and a metal film including a cylindrical portion that comes into contact with the gate electrode in the first direction and encloses the oxide semiconductor with the first insulating film interposed therebetween.

### CROSS-REFERENCE TO RELATED APPLICATION

This application is based upon and claims the benefit of priority from Japanese Patent Application No. 2023-148695, filed Sep. 13, 2023, the entire contents of which are incorporated herein by reference.

### FIELD

Embodiments described herein relate generally to a semiconductor device and a semiconductor memory device.

### BACKGROUND

Some semiconductor elements include oxide semiconductors.

### DESCRIPTION OF THE DRAWINGS

FIG. 1 is a circuit diagram illustrating a circuit configuration example of a memory cell array according to a first embodiment;

FIG. 2 is a sectional schematic view illustrating a structure example of a semiconductor memory device according to the first embodiment and a sectional view parallel to a ZX plane;

FIG. 3 is a sectional schematic view illustrating a structure example of a semiconductor device according to the first embodiment and a sectional view parallel to the ZX plane of the semiconductor device according to a first example of the first embodiment;

FIG. 4 is a sectional schematic view illustrating a structure example of the semiconductor device according to the first embodiment and a sectional view parallel to a YZ plane of the semiconductor device;

FIG. 5 is a sectional view taken along a cutting line V-V illustrated in FIGS. 3 and 4;

FIG. 6 is an enlarged view illustrating a connection portion of an upper electrode and an oxide semiconductor layer according to the first example of the first embodiment;

FIG. 7 is a sectional view parallel to the ZX plane illustrating a manufacturing process for the semiconductor device according to the first example of the first embodiment;

FIG. 8 is a sectional view parallel to the ZX plane illustrating a manufacturing process for the semiconductor device according to the first example of the first embodiment;

FIG. 9 is a sectional view parallel to the ZX plane illustrating a manufacturing process for the semiconductor device according to the first example of the first embodiment;

FIG. 10 is a sectional view parallel to the ZX plane illustrating a manufacturing process for the semiconductor device according to the first example of the first embodiment;

FIG. 11 is a sectional view parallel to the ZX plane illustrating a manufacturing process for the semiconductor device according to the first example of the first embodiment;

FIG. 12 is a sectional view parallel to the ZX plane illustrating a manufacturing process for the semiconductor device according to the first example of the first embodiment;

FIG. 13 is a sectional view parallel to the ZX plane illustrating a manufacturing process for the semiconductor device according to the first example of the first embodiment;

FIG. 14 is a sectional view parallel to the ZX plane illustrating a manufacturing process for the semiconductor device according to the first example of the first embodiment;

FIG. 15 is a sectional view parallel to the ZX plane illustrating a manufacturing process for the semiconductor device according to the first example of the first embodiment;

FIG. 16 is a sectional view parallel to the ZX plane illustrating a manufacturing process for the semiconductor device according to the first example of the first embodiment;

FIG. 17 is a sectional view parallel to the ZX plane illustrating a manufacturing process for the semiconductor device according to the first example of the first embodiment;

FIG. 18 is a sectional view parallel to the ZX plane illustrating a manufacturing process for the semiconductor device according to the first example of the first embodiment;

FIG. 19 is a sectional view parallel to the ZX plane illustrating a manufacturing process for the semiconductor device according to the first example of the first embodiment;

FIG. 20 is a sectional view parallel to the ZX plane illustrating a manufacturing process for the semiconductor device according to the first example of the first embodiment;

FIG. 21 is a sectional view parallel to the ZX plane illustrating a manufacturing process for the semiconductor device according to the first example of the first embodiment;

FIG. 22 is a sectional view parallel to the ZX plane illustrating a manufacturing process for the semiconductor device according to the first example of the first embodiment;

FIG. 23 is a sectional view parallel to the ZX plane illustrating a manufacturing process for the semiconductor device according to the first example of the first embodiment;

FIG. 24 is a sectional view parallel to the ZX plane illustrating a manufacturing process for the semiconductor device according to the first example of the first embodiment;

FIG. 25 is a sectional view parallel to the YZ plane illustrating a manufacturing process for the semiconductor device according to the first example of the first embodiment;

FIG. 26 is a sectional view parallel to the ZX plane illustrating a manufacturing process for the semiconductor device according to the first example of the first embodiment;

FIG. 27 is a sectional view parallel to the YZ plane illustrating a manufacturing process for the semiconductor device according to the first example of the first embodiment;

FIG. 28 is a sectional schematic view illustrating a structure example of the semiconductor device according to the first embodiment and a sectional view parallel to the ZX plane of a semiconductor device according to a second example of the first embodiment;

FIG. 29 is a sectional schematic view illustrating a structure example of the semiconductor device according to the first embodiment and a sectional view parallel to the YZ plane of the semiconductor device according to the second example of the first embodiment;

FIG. 30 is an enlarged view illustrating a connection portion of an upper electrode and an oxide semiconductor layer according to the second example of the first embodiment;

FIG. 31 is a sectional schematic view illustrating a structure example of the semiconductor device according to the first embodiment and a sectional view parallel to the ZX plane of a semiconductor device according to a third example of the first embodiment;

FIG. 32 is a sectional schematic view illustrating a structure example of the semiconductor device according to the first embodiment and a sectional view parallel to the YZ plane of the semiconductor device according to the third example of the first embodiment;

FIG. 33 is an enlarged view illustrating a connection portion of an upper electrode and an oxide semiconductor layer according to the third example of the first embodiment;

FIG. 34 is a sectional schematic view illustrating a structure example of the semiconductor device according to the first embodiment and a sectional view parallel to the ZX plane of a semiconductor device according to a fourth example of the first embodiment;

FIG. 35 is a sectional schematic view illustrating a structure example of the semiconductor device according to the first embodiment and a sectional view parallel to the YZ plane of the semiconductor device according to the fourth example of the first embodiment;

FIG. 36 is a sectional view parallel to the ZX plane illustrating a manufacturing process for the semiconductor device according to the fourth example of the first embodiment;

FIG. 37 is a sectional schematic view illustrating a structure example of the semiconductor device according to the first embodiment and a sectional view parallel to the ZX plane of a semiconductor device according to a fifth example of the first embodiment;

FIG. 38 is a sectional schematic view illustrating a structure example of the semiconductor device according to the first embodiment and a sectional view parallel to the YZ plane of the semiconductor device according to the fifth example of the first embodiment;

FIG. 39 is a sectional view parallel to the ZX plane illustrating a manufacturing process for the semiconductor device according to the fifth example of the first embodiment;

FIG. 40 is a sectional view parallel to the ZX plane illustrating a manufacturing process for the semiconductor device according to the fifth example of the first embodiment;

FIG. 41 is a sectional view parallel to the ZX plane illustrating a manufacturing process for the semiconductor device according to the fifth example of the first embodiment;

FIG. 42 is a sectional view parallel to the ZX plane illustrating a manufacturing process for the semiconductor device according to the fifth example of the first embodiment;

FIG. 43 is a sectional view parallel to the ZX plane illustrating a manufacturing process for the semiconductor device according to the fifth example of the first embodiment;

FIG. 44 is a sectional schematic view illustrating a structure example of a semiconductor device according to a second embodiment and a sectional view parallel to the ZX plane;

FIG. 45 is a sectional schematic view illustrating a structure example of the semiconductor device according to the second embodiment and a sectional view parallel to the YZ plane;

FIG. 46 is a sectional view parallel to the ZX plane illustrating a manufacturing process for the semiconductor device according to the second embodiment;

FIG. 47 is a sectional view parallel to the ZX plane illustrating a manufacturing process for the semiconductor device according to the second embodiment;

FIG. 48 is a sectional view parallel to the ZX plane illustrating a manufacturing process for the semiconductor device according to the second embodiment;

FIG. 49 is a sectional view parallel to the ZX plane illustrating a manufacturing process for the semiconductor device according to the second embodiment;

FIG. 50 is a sectional view parallel to the ZX plane illustrating a manufacturing process for the semiconductor device according to the second embodiment;

FIG. 51 is a sectional view parallel to the ZX plane illustrating a manufacturing process for the semiconductor device according to the second embodiment;

FIG. 52 is a sectional view parallel to the ZX plane illustrating a manufacturing process for the semiconductor device according to the second embodiment;

FIG. 53 is a sectional view parallel to the ZX plane illustrating a manufacturing process for the semiconductor device according to the second embodiment;

FIG. 54 is a sectional view parallel to the ZX plane illustrating a manufacturing process for the semiconductor device according to the second embodiment;

FIG. 55 is a sectional view parallel to the ZX plane illustrating a manufacturing process for the semiconductor device according to the second embodiment;

FIG. 56 is a sectional view parallel to the ZX plane illustrating a manufacturing process for the semiconductor device according to the second embodiment;

FIG. 57 is a sectional view parallel to the ZX plane illustrating a manufacturing process for the semiconductor device according to the second embodiment;

FIG. 58 is a sectional view parallel to the ZX plane illustrating a manufacturing process for the semiconductor device according to the second embodiment;

FIG. 59 is a sectional view parallel to the ZX plane illustrating a manufacturing process for the semiconductor device according to the second embodiment;

FIG. 60 is a sectional view parallel to the ZX plane illustrating a manufacturing process for the semiconductor device according to the second embodiment; and

FIG. 61 is a sectional view parallel to the ZX plane illustrating a manufacturing process for the semiconductor device according to the second embodiment.

### DETAILED DESCRIPTION

A technique for manufacturing a high-quality semiconductor device in a manufacturing process for a semiconductor element including an oxide semiconductor is required.

Embodiments provide semiconductor device and a semiconductor memory device that can be manufactured with high quality.

In general, according to one embodiment, a semiconductor device includes: an oxide semiconductor including a first end and a second end and extending in a first direction oriented from the second end to the first end; a first electrode configured to come into contact with the first end of the oxide semiconductor; a second electrode configured to come into contact with the second end of the oxide semiconductor; a gate electrode configured to enclose the oxide semiconductor with a first insulating film interposed therebetween between the first and second ends of the oxide semiconductor; and a metal film including a cylindrical portion that comes into contact with the gate electrode in the first direction and encloses the oxide semiconductor with the first insulating film interposed therebetween.

According to another embodiment, a semiconductor device includes: an oxide semiconductor including a first end and a second end and extending in a first direction oriented from the second end to the first end; a first electrode configured to come into contact with the first end of the oxide semiconductor; a second electrode configured to come into contact with the second end of the oxide semiconductor; a first insulating film configured to enclose at least a part of the oxide semiconductor in the first direction; a gate electrode configured to enclose the oxide semiconductor with the first insulating film interposed therebetween between the first and second ends of the oxide semiconductor; a third insulating film configured to come into contact with a part of a side surface of the first insulating film including an end portion in the first direction; and a fourth insulating film configured to come into contact with the third insulating film in a direction opposite to the first direction.

According to still another embodiment, a semiconductor device includes: an oxide semiconductor including a first end and a second end and extending in a first direction oriented from the second end to the first end; a first electrode configured to come into contact with the first end of the oxide semiconductor; a second electrode configured to come into contact with the second end of the oxide semiconductor; a first insulating film configured to enclose a part of the oxide semiconductor in the first direction; and a gate electrode configured to enclose the oxide semiconductor with the first insulating film interposed therebetween between the first and second ends of the oxide semiconductor, in which the second electrode is distant from an end portion of the first insulating film in a direction opposite to the first direction.

According to still another embodiment, a semiconductor memory device includes: the semiconductor device; a first capacity electrode connected to the first or second electrode; a second capacity electrode facing the first capacitor electrode; and a dielectric film provided between the first and second capacitor electrodes.

Hereinafter, embodiments will be described with reference to the appended drawings. To facilitate understanding of description, the same reference numerals are given to the same elements in each drawing as much as possible and repeated description thereof will be omitted.

### First Embodiment

A configuration of a semiconductor memory device according to a first embodiment will be described. In each drawing, X, Y, and Z axes may be illustrated. The X, Y, and Z axes form right-handed type 3-dimensional rectangular coordinates. Hereinafter, an arrow direction of the X axis may be referred to as the +X axis direction and its opposite direction may be referred to as the −X axis direction, and the same applies to the other axes. The +Z axis direction and the −Z axis direction may be referred to as an “upper side” and a “lower side”, respectively. Planes orthogonal to the X, Y, and Z axes may be referred to as a YZ plane, an ZX plane, and an XY plane, respectively. The Z axis direction may be referred to as a “vertical direction”. The “upper direction”, the “lower direction”, and “the vertical direction” are merely terms indicating relative positional relations in the drawings, and are not terms defined using a perpendicular direction as a reference.

Unless otherwise specified, dimensions and the like of elements illustrated in each drawing may be different from actual dimensions to facilitate understanding of description.

In the present application, “connection” encompasses not only physical connection but also electric connection and, unless otherwise specified, the connection encompasses not only direct connection but also indirect connection.

In the present application, “forming above” encompasses not only a case of forming in contact with the upper side but also a case of forming with another interposed therebetween unless otherwise specified. The same applies to a case of “forming below”.

A semiconductor memory device 101 according to the first embodiment is an oxide semiconductor-random access memory (OS-RAM) and includes a memory cell array.

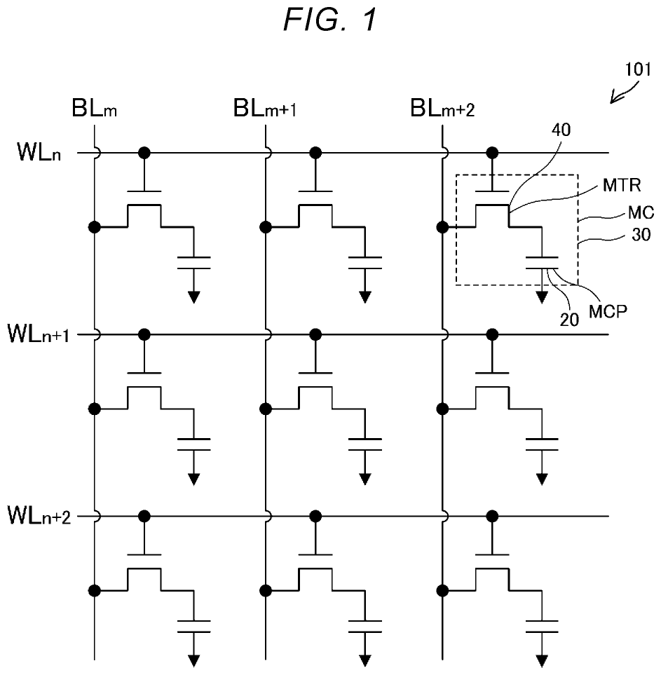

As illustrated in FIG. 1, the memory cell array includes a plurality of memory cells MC, a plurality of word lines WL, and a plurality of bit lines BL.

In FIG. 1, as examples of the plurality of word lines WL, word lines WLₙ, WLₙ₊₁, and WLₙ₊₂ (where n is a positive integer) are illustrated. In FIG. 1, as examples of the bit lines BL, bit lines BLₘ, BLₘ₊₁, and BLₘ₊₂ (where m is a positive integer) are illustrated. The number of memory cells MC is not limited to the number illustrated in FIG. 1.

The plurality of memory cells MC are located in, for example, a matrix configuration to form a memory cell array. The memory cell MC includes a memory transistor MTR that is a field-effect transistor (FET) and a memory capacitor MCP.

A series of memory cells MC provided in a row direction are connected to a word line WL (for example, the word line WLₙ) corresponding to a row (for example, an n-th row) to which the memory cells MC belong. A series of memory cells MC provided in a column direction are connected to a bit line BL (for example the bit line BLₘ₊₂) corresponding to a column (for example, an m+2-th column) to which the memory cells MC belong.

More specifically, a gate of the memory transistor MTR in the memory cell MC is connected to a word line WL corresponding to the row to which the memory cell MC belongs. One of a source or a drain of the memory transistor MTR is connected to a bit line BL corresponding to the column to which the memory cell MC belongs.

One electrode of the memory capacitor MCP in the memory cell MC is connected to the other of the source or the drain of the memory transistor MTR in the memory cell MC. The other electrode of the memory cell MC is connected to a power line (not illustrated) through which a specific voltage is supplied.

The memory cell MC is configured such that data can be stored by storing charges in the memory capacitor MCP by a current flowing in the corresponding bit line BL through switching of the memory transistor MTR based on a voltage of the corresponding word line WL.

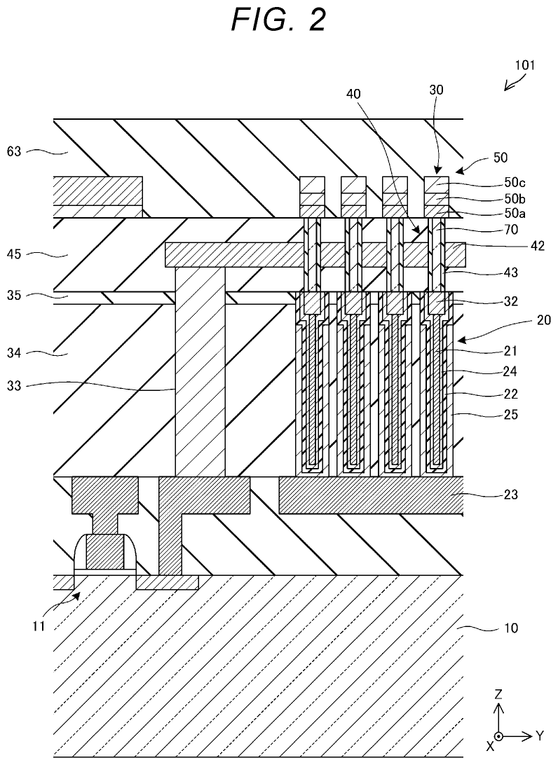

As illustrated in FIG. 2, the semiconductor memory device 101 includes a semiconductor substrate 10, a circuit 11, a capacitor 20, a semiconductor device 30, a conductor 33, and insulating layers 34, 35, 45, and 63.

The capacitor 20 includes a conductor 21, an insulating film 22 (which is an example of a “dielectric film”), a conductor 23, a capacitor electrode 24 (which is an example of a “first capacitor electrode”), and a capacitor electrode 25 (which is an example of a “second capacitor electrode”).

The semiconductor device 30 includes a field-effect transistor 40 (which is an example of a “semiconductor element”), an upper electrode 50 (which is an example of a “first electrode”) provided above the field-effect transistor 40, and a lower electrode 32 (which is an example of a “second electrode”) provided below the field-effect transistor 40.

The field-effect transistor 40 includes an oxide semiconductor layer 70 (which is an example of an “oxide semiconductor”) corresponding to a channel, a gate insulating film 43 (which is an example of a “first insulating film”), and a conductive layer 42 (which is an example of a “gate electrode”).

The oxide semiconductor layer 70 is formed in the insulating layer 45 and includes an upper end 70a (which is a “first end”) and a lower end 70b (which is an example of a “second end”). The oxide semiconductor layer 70 is a columnar body extending in the +Z axis direction (which is an example of a “first direction”) oriented from the lower end 70b to the upper end 70a. The oxide semiconductor layer 70 forms a channel of the field-effect transistor 40 and the oxide semiconductor layer 70 has an amorphous structure. The conductive layer 42 contains, for example, tungsten.

The conductive layer 42 functions as a gate electrode of the field-effect transistor 40 and encloses the oxide semiconductor layer 70 with the gate insulating film 43 interposed therebetween between the upper end 70a and the lower end 70b of the oxide semiconductor layer 70.

The gate insulating film 43 includes, for example, a silicon nitride film (Si₃N₄) containing silicon and nitrogen.

The upper electrode 50 is formed in the +Z axis direction with respect to the oxide semiconductor layer 70 and comes into contact with the upper end 70a of the oxide semiconductor layer 70. The upper electrode 50 includes a metal oxide layer 50a, a barrier metal layer 50b, and a metal film 50c.

The metal film 50c contains tungsten (W). The metal oxide layer 50a is formed between the metal film 50c and the upper end 70a of the oxide semiconductor layer 70 and contains metal oxide. The metal oxide contains, for example, indium and tin as metal elements. In the embodiment, the metal oxide layer 50a is formed of indium tin oxide (ITO).

The barrier metal layer 50b contains titanium and nitrogen and is formed between the metal oxide layer 50a and the metal film 50c. In the embodiment, the barrier metal layer 50b is formed of, for example, titanium nitride (TiN).

The lower electrode 32 comes into contact with the lower end 70b of the oxide semiconductor layer 70. The lower electrode 32 is formed by, for example, an ITO layer containing metal oxide such as indium tin oxide (ITO).

The lower electrode 32 is not limited to ITO and may contain at least one of elements including indium, tin, zinc, cadmium, gold, silver, platinum, lead, copper, nickel, tungsten, and iron.

The circuit 11 is provided in a peripheral circuit such as a decoder that selects a predetermined memory cell MC among the plurality of memory cells MC of the semiconductor memory device 101, that is, the capacitor 20 and the field-effect transistor 40, a sense amplifier connected to the bit lines BL, or a register configured with an SRAM. The circuit 11 may include a CMOS circuit that includes field-effect transistors of a P-channel type field-effect transistor (Pch-FET) and an N-channel type field-effect transistor (Nch-FET) formed by a CMOS process.

The field-effect transistor of the circuit 11 can be formed using, for example, the semiconductor substrate 10 such as a monocrystal silicon substrate. The Pch-FET and the Nch-FET are each a so-called lateral field-effect transistor that includes a channel region, a source region, and a drain region in the semiconductor substrate 10, and includes a channel for causing carriers to flow in the X axis direction or the Y axis direction substantially parallel to the surface of the semiconductor substrate 10 in a region close to the surface of the semiconductor substrate 10. The semiconductor substrate 10 may have a P-type or N-type conductive type. In FIG. 2, an example of a field-effect transistor of the circuit 11 is illustrated for convenience.

The capacitor 20 is the memory capacitor MCP in the memory cell MC (see FIG. 1). In FIG. 2, four capacitors 20 are illustrated, but the number of capacitors 20 is not limited to four.

In the embodiment, the capacitor 20 is provided above the semiconductor substrate 10. The capacitor electrode 24 in the capacitor 20 is connected to the conductor 21 and the lower electrode 32. The capacitor electrode 25 faces the capacitor electrode 24. The insulating film 22 is provided between the capacitor electrodes 24 and 25.

The capacitor 20 is a 3-dimensional capacitor such as a pillar type capacitor. Another capacitor that has a configuration in which charges can be stored may be used as a capacitor in the embodiment.

The conductor 21 has a shape coming into contact with the lower end surface of the lower electrode 32 and extending from the end portion to the lower side. The capacitor electrode 24 covers the lower electrode 32 and the conductor 21. The insulating film 22 covers the capacitor electrode 24. The capacitor electrode 25 includes a lower end enclosing a lower part of the insulating film 22 and coming into contact with the upper end surface of the conductor 23.

The conductor 21 may contain a material such as amorphous silicon. The insulating film 22 may contain a material such as hafnium oxide. The conductor 23 and the capacitor electrodes 24 and 25 may contain materials such as tungsten (W) and titanium nitride (TiN).

The conductor 33 includes a wiring electrically connecting the circuit 11 to the semiconductor device 30. The conductor 33 may include a via wiring and includes, for example, a via wiring that extends in the Z axis direction and connects the word line WL to the circuit 11 provided on the semiconductor substrate 10, as illustrated in FIG. 2. The conductor 33 contains, for example, copper.

The insulating layer 34 is provided between the plurality of capacitors 20. The insulating layer 34 is, for example, a silicon oxide film that contains silicon and oxygen.

The insulating layer 35 is provided above the insulating layer 34. The insulating layer 35 is, for example, a silicon nitride film that contains silicon and nitrogen.

The semiconductor device 30 is provided above the capacitor 20. The field-effect transistor 40 in the semiconductor device 30 corresponds to the memory transistor MTR of the memory cell MC (see FIG. 1).

In the semiconductor device 30, the field-effect transistor 40 is provided above the lower electrode 32. More specifically, the oxide semiconductor layer 70 of the field-effect transistor 40 is located in a direction away from the semiconductor substrate 10 with respect to the lower electrode 32, that is, on the upper side.

The upper electrode 50 is located in a direction away from the semiconductor substrate 10 with respect to the oxide semiconductor layer 70, that is, the upper side. In such configuration, the field-effect transistor 40 is a so-called vertical transistor that includes a channel extending in the Z axis direction (the vertical direction) substantially vertical to the surface of the semiconductor substrate 10.

The oxide semiconductor layer 70 is a semiconductor in which oxygen deficiency is a doner and contains indium (In), zinc (Zn), and gallium (Ga) as metal elements. More specifically, the oxide semiconductor layer 70 is an oxide of indium, gallium, and zinc, that is, InGaZnO (IGZO). The oxide semiconductor layer 70 may be another type of oxide semiconductor.

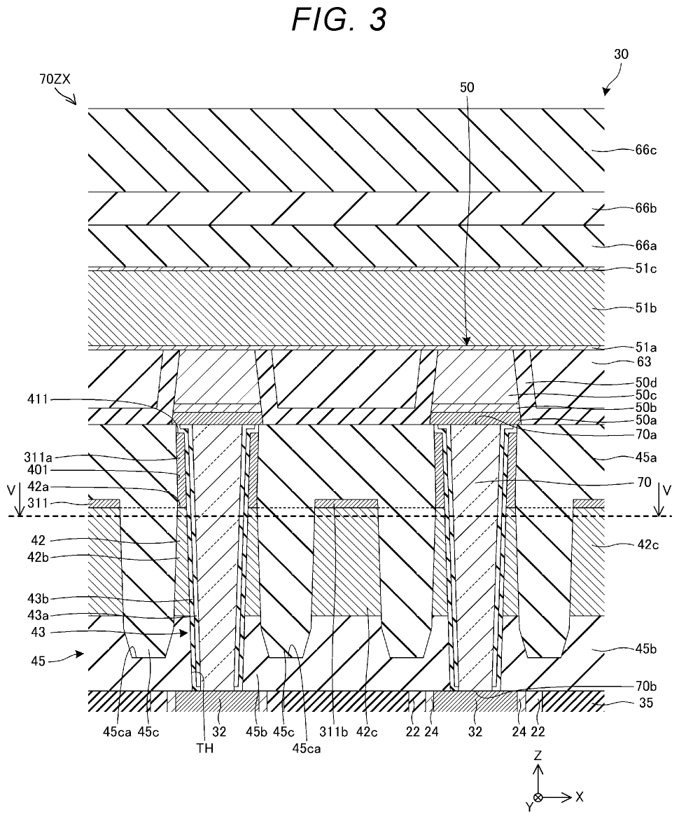

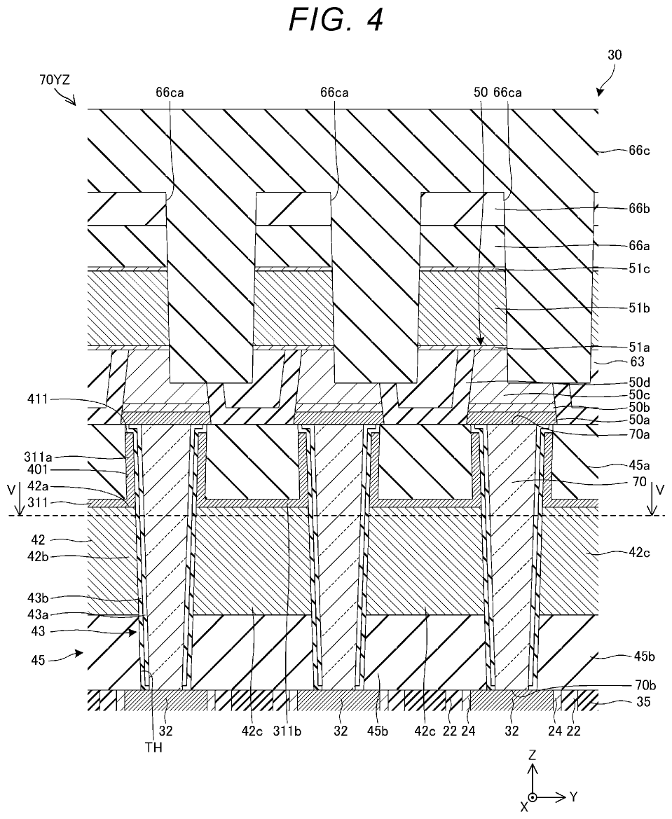

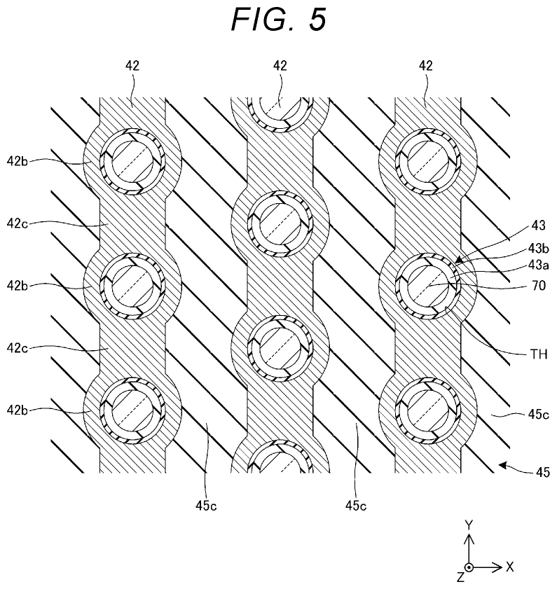

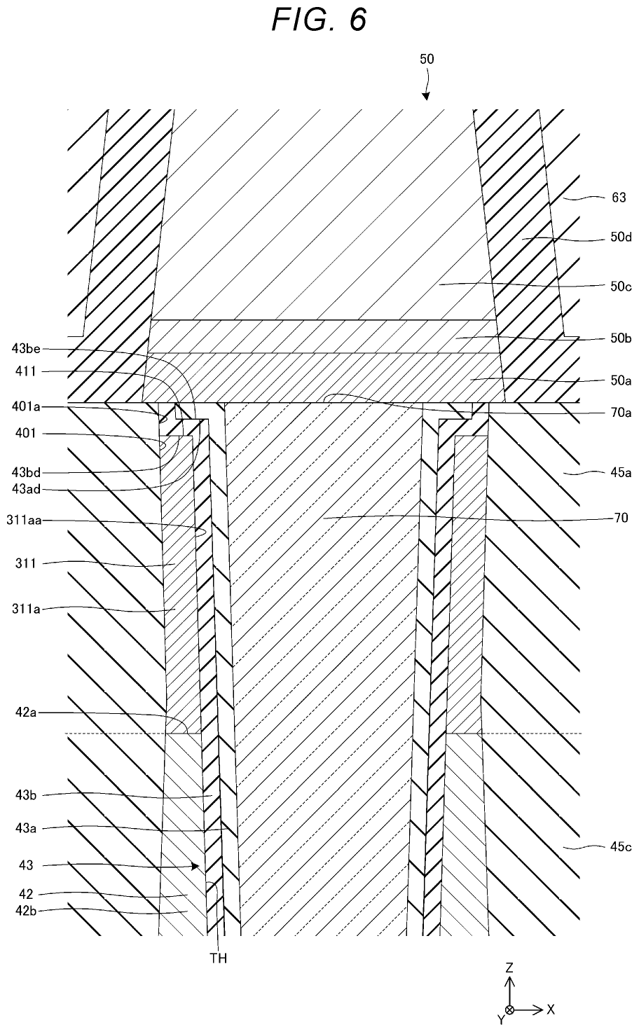

FIG. 3 illustrates a cross section 70ZX parallel to the ZX plane and a sectional view of the semiconductor device 30 when viewed on the cross section 70ZX in the oxide semiconductor layer 70. FIG. 4 illustrates a cross section 70YZ parallel to the YZ plane and a sectional view of the semiconductor device 30 when viewed on the cross section 70YZ in the oxide semiconductor layer 70. FIG. 5 is a sectional view taken along a cutting line V-V illustrated in FIGS. 3 and 4. FIG. 6 is an enlarged view illustrating a connection portion of the upper electrode and the oxide semiconductor layer.

Hereinafter, a first example of the semiconductor device 30 in the first embodiment (hereinafter also referred to as the first example of the first embodiment) will be described.

### First Example of First Embodiment

As illustrated in FIGS. 3 to 6, in the first example of the first embodiment, the semiconductor device 30 further includes a metal spacer film 311 (which is an example of a “metal film”). The gate insulating film 43 includes insulating films 43a and 43b. The insulating layer 45 includes insulating films 45a, 45b, and 45c.

The plurality of conductive layers 42 are repeatedly provided in the +X axis direction. The plurality of oxide semiconductor layers 70 are located 2-dimensionally. That is, some of the plurality of oxide semiconductor layers 70 are provided in the +Y axis direction (which is an example of a “second direction”). Some of the plurality of oxide semiconductor layers 70 are provided in the +X axis direction.

The conductive layers 42 extend in the +Y axis direction and enclose the plurality of oxide semiconductor layers 70 provided in the +Y axis direction with the plurality of gate insulating films 43 interposed therebetween.

More specifically, the conductive layers 42 include a plurality of enclosure portions 42b and at least one connection portion 42c. The plurality of enclosure portions 42b respectively enclose the plurality of oxide semiconductor layers 70 with the gate insulating films 43 interposed therebetween. The connection portion 42c connects the enclosure portions 42b to each other.

When the conductive layer 42 is viewed from the upper side, a width of the connection portion 42c in the X axis direction is narrower than a width of the enclosure portion 42b in the X axis direction (see FIG. 5).

The metal spacer film 311 is provided on the +Z axis direction side of the conductive layer 42. The metal spacer film 311 contains, for example, titanium, tantalum, tungsten, platinum, ruthenium, nickel, cobalt, palladium, gold or copper, or nitride of titanium, tantalum, and tungsten. The metal spacer film 311 includes a plurality of cylinder portions 311a (each of which is an example of a “cylindrical portion”) and at least one plate portion 311b.

The plurality of cylinder portions 311a come into contact with the +Z axis direction side of the plurality of enclosure portions 42b in the conductive layers 42. The plurality of cylinder portions 311a enclose the plurality of oxide semiconductor layers 70 with the gate insulating films 43 interposed therebetween.

More specifically, the lower end portion of the cylinder portion 311a is an annular surface coming into contact with the upper surface 42a of the conductive layer 42. The upper end portion of the cylinder portion 311a is an annular surface and does not come into contact with the upper electrode 50.

Both ends of the plate portion 311b come into contact with two cylinder portions 311a adjacent in the Y axis direction. The plate portion 311b is provided above the connection portion 42c and has a bottom surface coming into contact with the connection portion 42c. The plate portion 311b extends to be substantially parallel to the XY plane.

The insulating films 45a and 45b are respectively provided above and below the conductive layer 42. The insulating films 45a and 45b are, for example, oxide of silicon. In the insulating film 45a, a hole portion 401 (which is an example of a “first hole portion”) through which the oxide semiconductor layer 70 penetrates is formed (see FIG. 6).

The cylinder portion 311a of the metal spacer film 311 is inserted into a part of the hole portion 401 in the −Z axis direction (see FIG. 6). A step portion 411 (which is an example of a “first step portion”) is formed by the hole portion 401 and the cylinder portion 311a. More specifically, the step portion 411 is formed between an inner surface 401a of the hole portion 401 above the cylinder portion 311a and an inner circumferential surface 311aa of the cylinder portion 311a.

The insulating film 45c partitions two conductive layers 42 adjacent in the +X axis direction. More specifically, the insulating film 45c is located between two conductive layers 42 in the +X axis direction and extends to be substantially parallel to the Y axis.

The upper end portion of the insulating film 45c comes into contact with the lower surface of the insulating film 45a. The lower end portion of the insulating film 45c is filled with the insulating film 45b. In the embodiment, the insulating films 45a and 45c are integrally formed.

The gate insulating film 43 has a cylindrical shape and encloses the entire circumference of a side surface of the oxide semiconductor layer 70. The gate insulating film 43 is bent along the inner circumferential surface 311aa of the cylinder portion 311a and the step portion 411 to form a step portion 43bd (which is an example of a “second step portion”) coming into contact with the step portion 411 on the outer circumferential surface of the gate insulating film 43. A step portion is not formed on the inner circumferential surface of the gate insulating film 43.

More specifically, the gate insulating film 43 includes the cylindrical insulating film 43b (which is an example of a “first film”) and the cylindrical insulating film 43a (which is an example of a “second film”). The insulating film 43a contains, for example, oxide of silicon. The insulating film 43b contains, for example, nitride of silicon.

The insulating film 43a is provided between the insulating film 43b and the oxide semiconductor layer 70. That is, the gate insulating film 43 is configured with two layers of the insulating film 43b and the insulating film 43a disposed closer to the oxide semiconductor layer 70 than the insulating film 43b.

The insulating film 43b is bent along the inner circumferential surface 311aa of the cylinder portion 311a, the step portion 411, and the inner wall 401a of the hole portion 401. By the bending, the step portion 43bd and a step portion 43be (which is an example of a “fifth step portion”) are respectively formed on the outer circumferential surface and the inner circumferential surface of the insulating film 43b.

The insulating film 43a is bent along the inner circumferential surface 311aa of the cylinder portion 311a and the step portion 411 via the insulating film 43b. By the bending, a step portion 43ad (which is an example of a “sixth step portion”) is formed on the outer circumferential surface of the insulating film 43a. The step portion 43ad comes into contact with the step portion 43be of the insulating film 43b. Meanwhile, a step portion is not formed on the inner circumferential surface of the insulating film 43a.

The upper end surfaces of the insulating films 43a 43b come into contact with the metal oxide layer 50a in the upper electrode 50, respectively. That is, the upper side of the gate insulating film 43 spreads outward between the upper end portion of the cylinder portion 311a and the upper electrode 50. A distance between the upper electrode 50 and the upper end portion of the cylinder portion 311a is 4 nm or more and 30 nm or less.

### Method of Manufacturing Semiconductor Device

Hereinafter, a method of manufacturing the semiconductor device 30 will be described as an example of a method of manufacturing a semiconductor device according to the first embodiment.

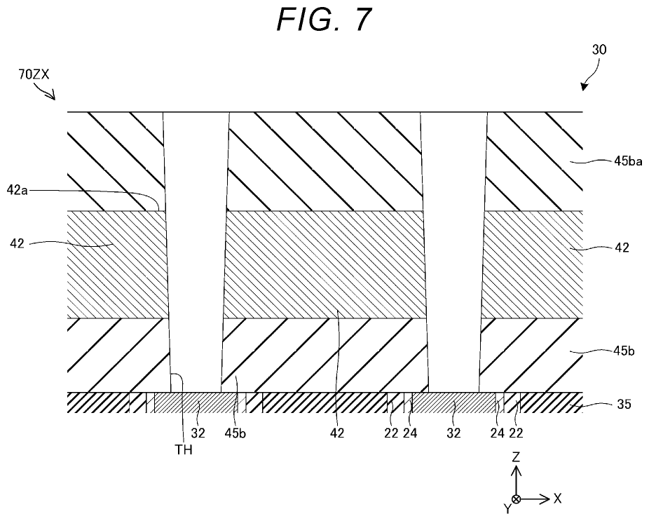

First, as illustrated in FIG. 7, the insulating film 45b, the conductive layer 42, and the insulating film 45ba are provided in this order above the insulating layer 35. The insulating film 45b, the conductive layer 42, and the insulating film 45ba extend to be substantially parallel to the XY plane. A transistor hole TH (which is an example of a “second hole portion”) which extends to be substantially parallel to the Z axis and through which the insulating film 45ba, the conductive layer 42, and the insulating film 45b penetrate is formed, and then is cleaned. The lower electrode 32 is exposed on a bottom of the transistor hole TH.

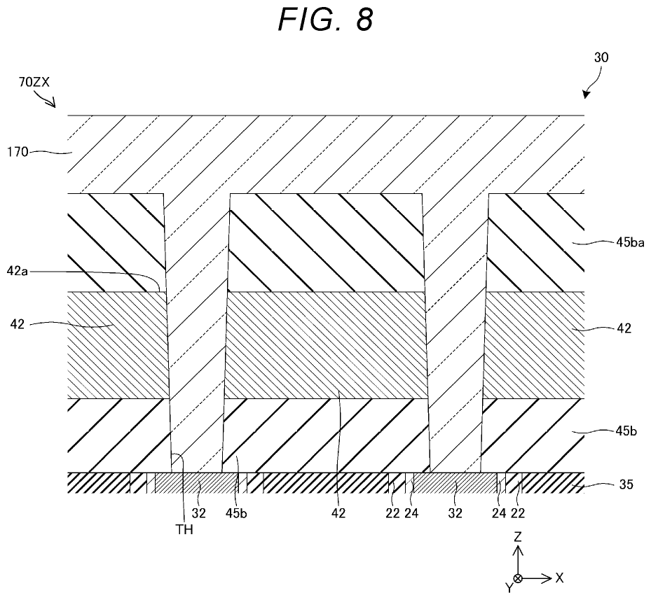

Subsequently, as illustrated in FIG. 8, a sacrifice amorphous silicon layer 170 is formed above the semiconductor device 30. Accordingly, the transistor hole TH is filled with the sacrifice amorphous silicon layer 170.

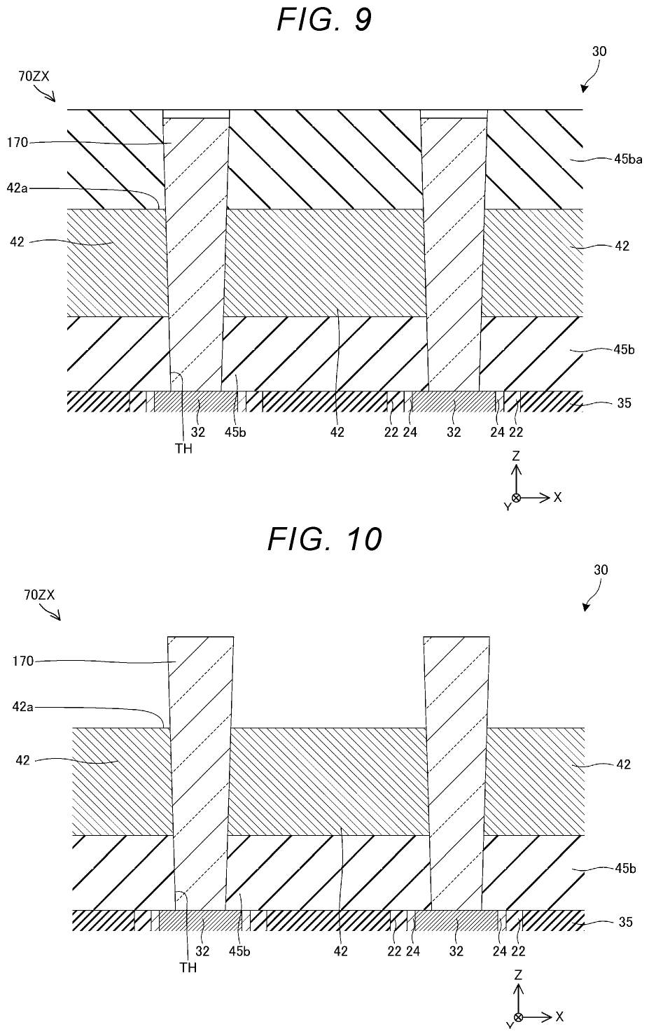

Subsequently, as illustrated in FIG. 9, by etching back the sacrifice amorphous silicon layer 170, an upper part of the sacrifice amorphous silicon layer 170 is removed and the upper surface of the insulating film 45ba is exposed. Here, in the transistor hole TH, the upper end portion of the sacrifice amorphous silicon layer 170 is located below an opening of the transistor hole TH and is located above the conductive layer 42.

Subsequently, as illustrated in FIG. 10, the insulating film 45ba is removed by etching.

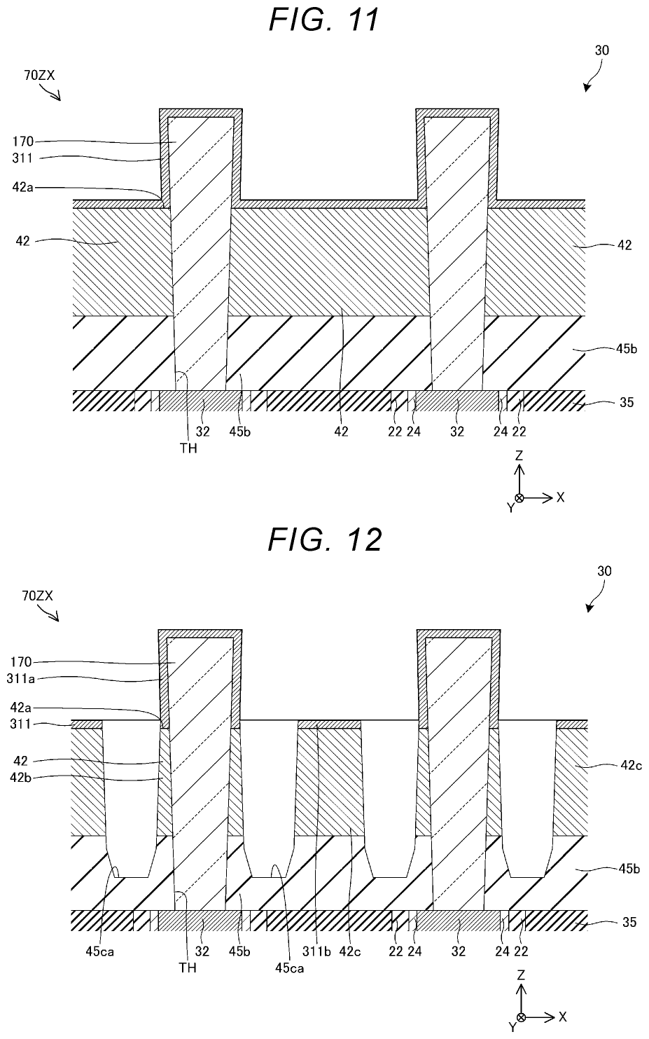

Subsequently, as illustrated in FIG. 11, the metal spacer film 311 is formed above the semiconductor device 30. Accordingly, the sacrifice amorphous silicon layer 170 exposed above the conductive layer 42 and the upper surface 42a of the conductive layer 42 are covered with the metal spacer film 311.

Subsequently, as illustrated in FIG. 12, film forming, resist coating, exposure, development, separation, and the like are performed on the surface of the semiconductor device 30 by a lithographic method to form a mask. Thereafter, in the semiconductor device 30, a groove portion 45ca penetrating until the insulating film 45b and extending to be substantially parallel to the Y axis is formed by etching. Accordingly, the metal spacer film 311 is separated from the cylinder portion 311a and the plate portion 311b. The conductive layers 42 extend to be substantially parallel to the Y axis and are separated into a plurality of electrodes repeatedly provided in the +X axis direction. The electrodes correspond to the word lines WL (see FIG. 1).

The enclosure portion 42b in the conductive layer 42 is formed self-aligned with the transistor hole TH (self-align-process). More specifically, even when a mask formation position by the lithographic method deviates, the cylinder portion 311a of the metal spacer film 311 provided on the side surface of the sacrifice amorphous silicon layer 170 functions as a mask. Therefore, the enclosure portion 42b in the conductive layer 42 is self-aligned around the transistor hole TH.

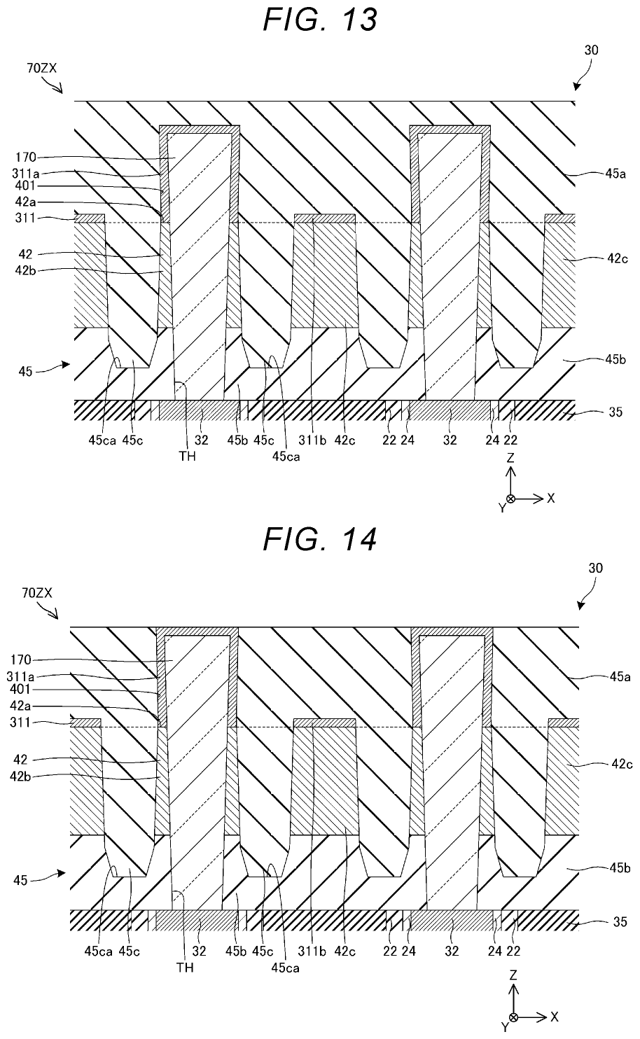

Subsequently, as illustrated in FIG. 13, the insulating films 45c and 45a are integrally formed above the semiconductor device 30.

Subsequently, as illustrated in FIG. 14, chemical mechanical polishing is performed on the upper surface of the semiconductor device 30, so that the upper surface of the metal spacer film 311 is exposed from the insulating film 45a.

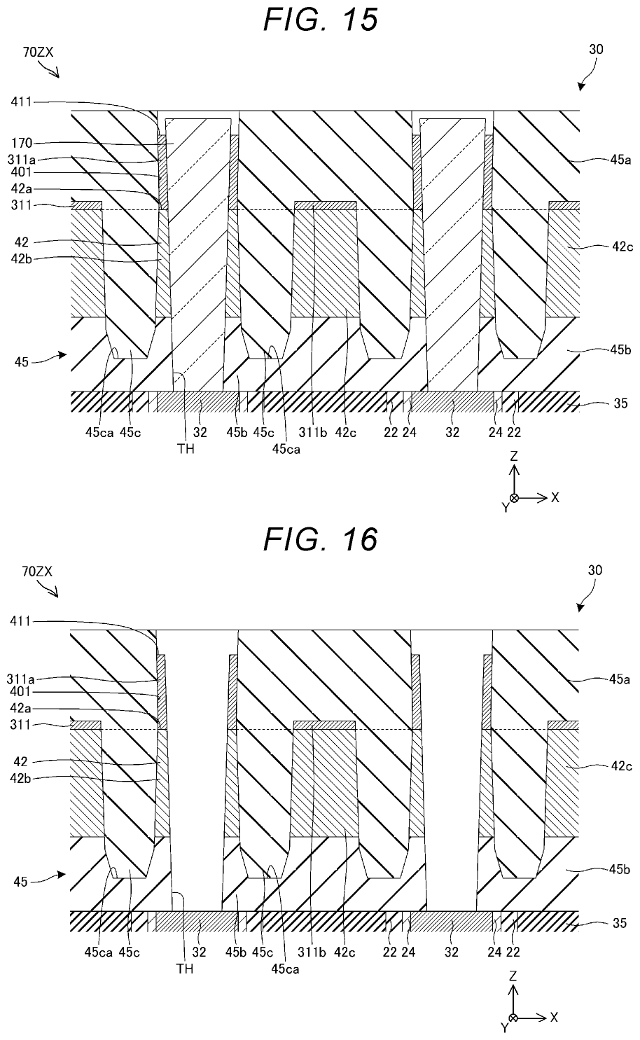

Subsequently, as illustrated in FIG. 15, an upper part of the metal spacer film 311 is removed by etching. Accordingly, the step portion 411 located at the upper end portion in the cylinder portion 311a of the metal spacer film 311 is formed. A height of the cylinder portion 311a in the vertical direction can be adjusted according to an etching amount of the metal spacer film 311. In other words, a position of the step portion 411 in the vertical direction can be adjusted according to the etching amount of the metal spacer film 311.

Subsequently, as illustrated in FIG. 16, the sacrifice amorphous silicon layer 170 in the transistor hole TH is removed by etching.

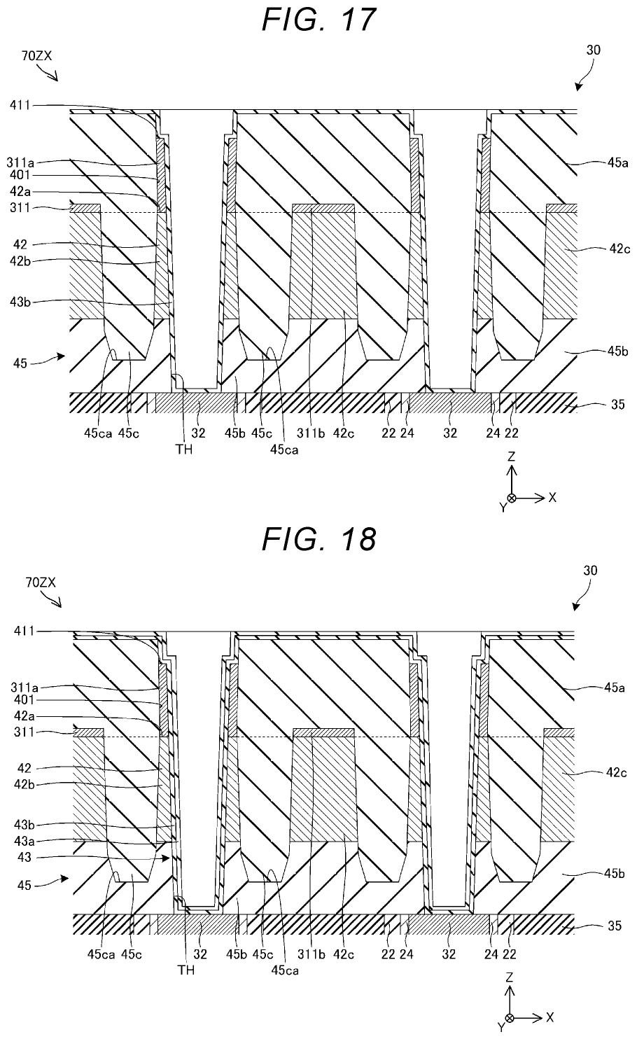

Subsequently, as illustrated in FIG. 17, the insulating film 43b is formed above the semiconductor device 30. Subsequently, as illustrated in FIG. 18, the insulating film 43a is formed above the semiconductor device 30.

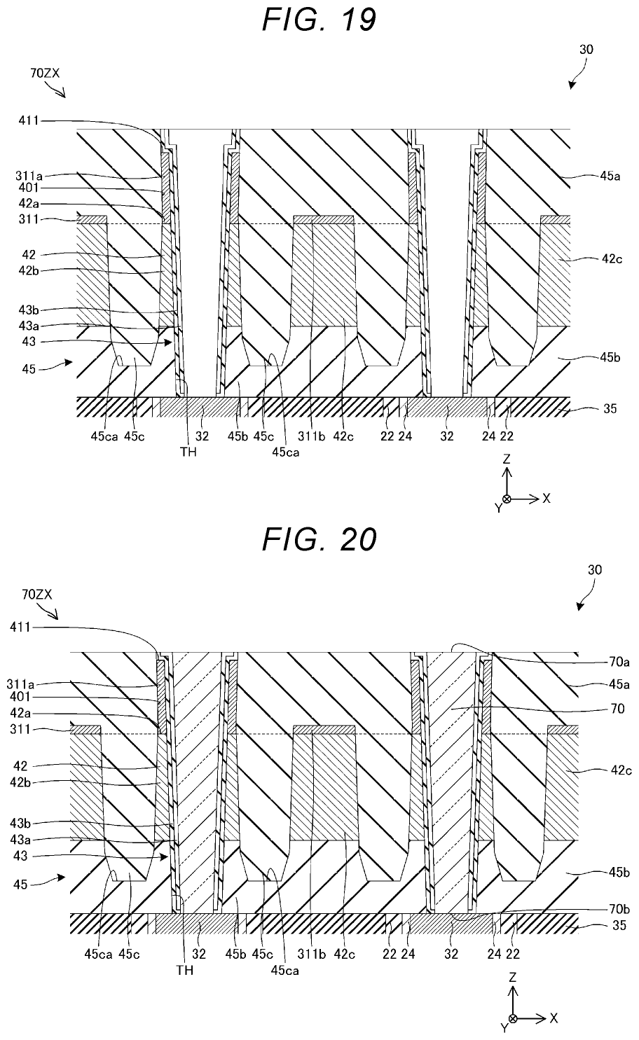

Subsequently, as illustrated in FIG. 19, the upper portion of the semiconductor device 30 is etched back by reactive ion etching, so that the insulating film 45a is exposed and the lower electrode 32 is exposed on the bottom of the transistor hole TH.

Subsequently, as illustrated in FIG. 20, the oxide semiconductor layer 70 is formed in the transistor hole TH. Then, chemical mechanical polishing is performed on the upper surface of the semiconductor device 30.

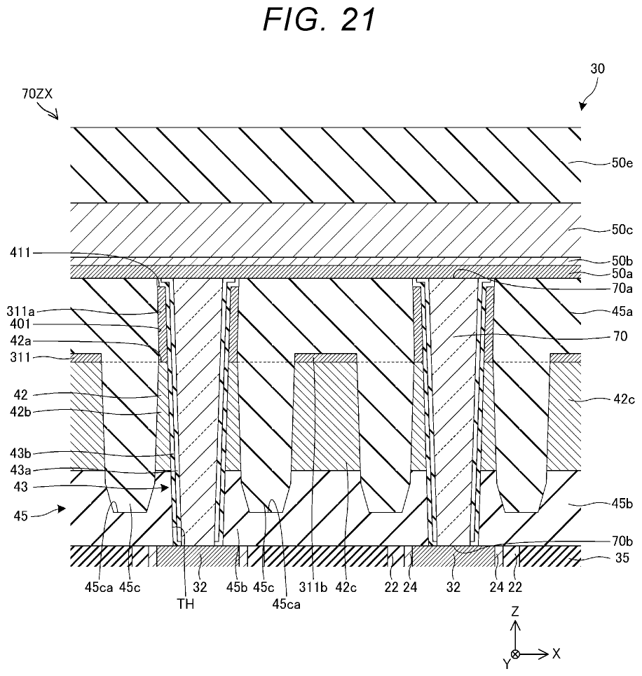

Subsequently, as illustrated in FIG. 21, the metal oxide layer 50a, the barrier metal layer 50b, and the metal film 50c are formed from the lower side to the upper side on the upper surface of the semiconductor device 30. Then, for example, a landing pad hard mask (LPHM) film 50e containing oxide of silicon is formed above the metal film 50c.

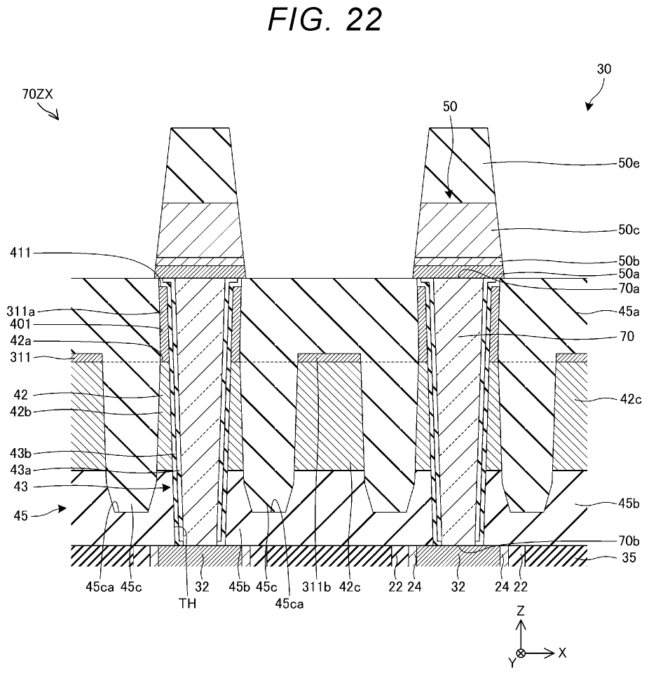

Subsequently, as illustrated in FIG. 22, film forming, resist coating, exposure, development, separation, and the like are performed on the surface of the semiconductor device 30 by a lithographic method to form a mask. Thereafter, in the semiconductor device 30, the upper electrode 50 functioning as a landing pad is formed by etching. The upper electrode 50 includes the metal oxide layer 50a, the barrier metal layer 50b, and the metal film 50c.

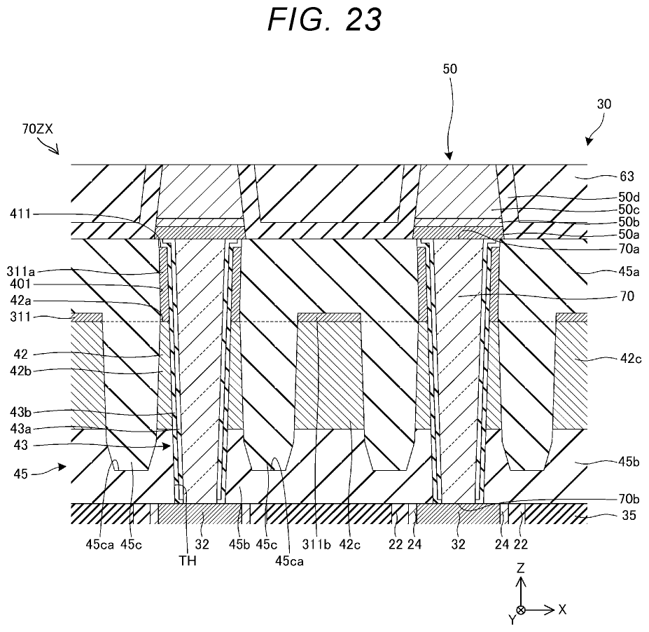

Subsequently, as illustrated in FIG. 23, an LP liner film 50d containing, for example, oxide of silicon is formed on the upper surface of the semiconductor device 30. An insulating layer 63 for filling a gap made by the LP liner film 50d is formed above the LP liner film 50d. The insulating layer 63 contains, for example, oxide of silicon. Then, chemical mechanical polishing is performed on the upper surface of the semiconductor device 30.

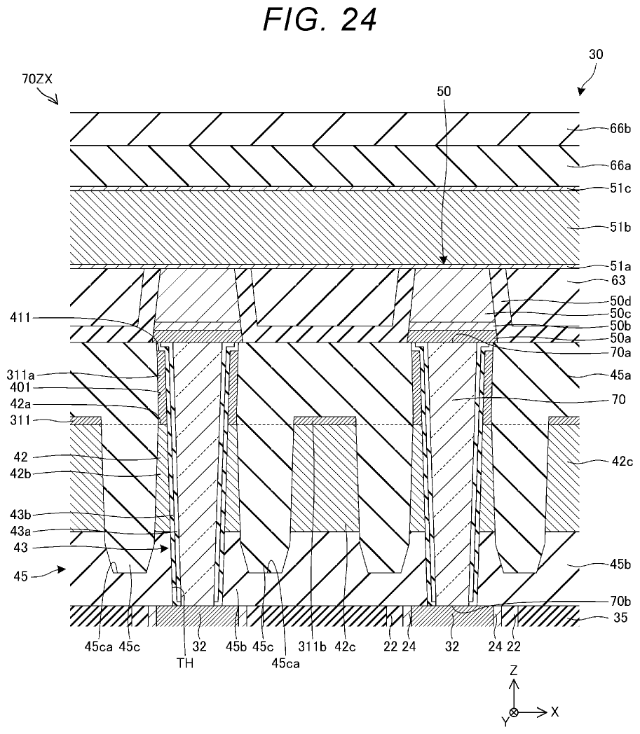

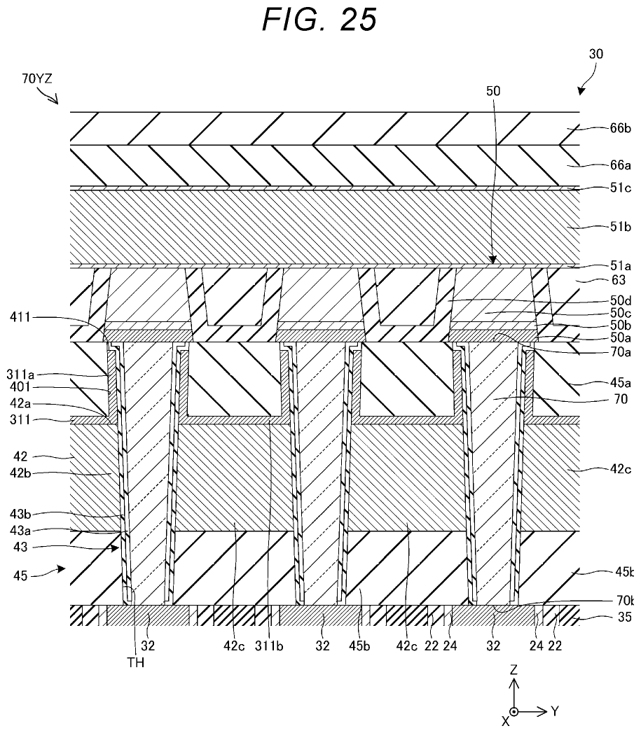

Subsequently, as illustrated in FIGS. 24 and 25, a barrier metal layer 51a, a conductive layer 51b, and a barrier metal layer 51c are formed from the lower side to the upper side on the upper surface of the semiconductor device 30. The barrier metal layers 51a and 51c contain, for example, titanium nitride. The conductive layer 51b contains, for example, tungsten.

Bit line hard mask (BLHM) films 66a and 66b are formed from the lower side to the upper side on the upper surface of the barrier metal layer 51c. The BLHM films 66a and 66b respectively contain, for example, nitride of silicon and oxide of silicon.

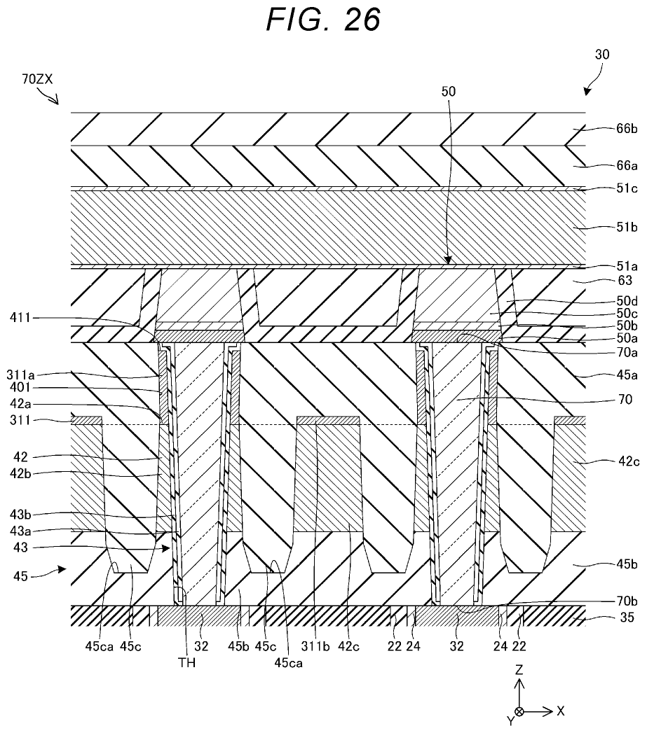

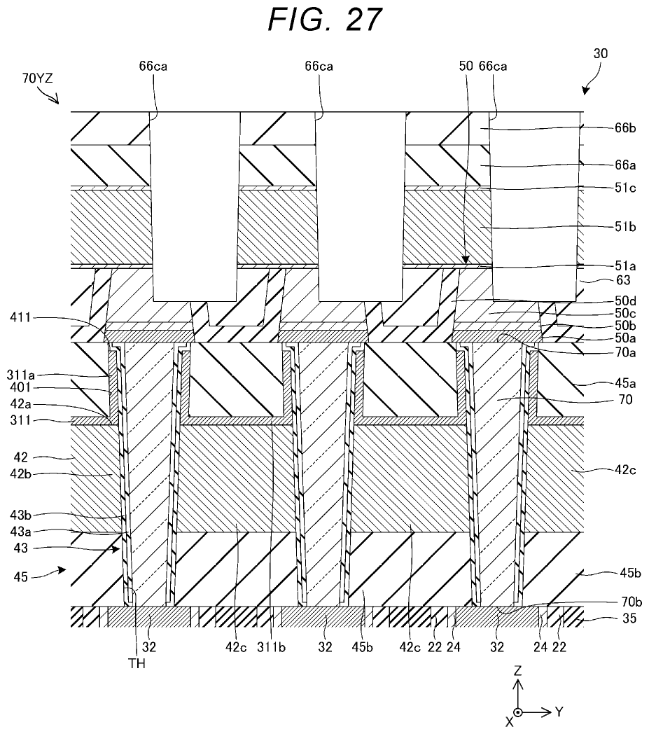

Subsequently, as illustrated in FIGS. 26 and 27, film forming, resist coating, exposure, development, separation, and the like are performed on the surface of the semiconductor device 30 by a lithographic method to form a mask. Thereafter, in the semiconductor device 30, a groove portion 66ca penetrating until the insulating film 63 and the metal film 50c and extending to be substantially parallel to the X axis is formed by etching. Accordingly, the barrier metal layer 51a, the conductive layer 51b, and the barrier metal layer 51c extend to be substantially parallel to the X axis and are separated into a plurality of electrodes repeatedly provided in the +Y axis direction. The electrodes correspond to the bit lines BL (see FIG. 1).

Subsequently, as illustrated in FIGS. 3 and 4, the insulating film 66c with which the groove portion 66ca is filled is formed above the semiconductor device 30. The insulating film 66c contains, for example, oxide of silicon.

### Advantages

When chemical mechanical polishing is performed on the upper surface of the semiconductor device 30 after formation of the insulating film 45a (see FIG. 14) and the upper surface of the sacrifice amorphous silicon layer 170 is polished to be exposed from the insulating film 45a, the sacrifice amorphous silicon layer 170 may be excessively polished at the end portion of an array region where the 2-dimensionally located transistor holes TH are provided.

In the embodiment, as illustrated in FIG. 14, when chemical mechanical polishing is performed on the semiconductor device 30 after formation of the insulating film 45a, the polishing is completed at a location where the upper surface of the metal spacer film 311 is exposed from the insulating film 45a. Accordingly, it is possible to inhibit excessive polishing of the sacrifice amorphous silicon layer 170 at the end portion of the array region.

With the configuration in which the conductive cylinder portion 311a is formed above the enclosure portion 42b of the conductive layer 42, it is possible to expand an area of the gate electrode. Accordingly, it is possible to reduce electric resistance of the word line WL. Since a channel region which is turned on in the oxide semiconductor layer 70 can be increased, an on-current Ion can be increased.

Hereinafter, a second example of the semiconductor device 30 in the first embodiment (hereinafter also referred to as the second example of the first embodiment) will be described.

### Second Example of First Embodiment

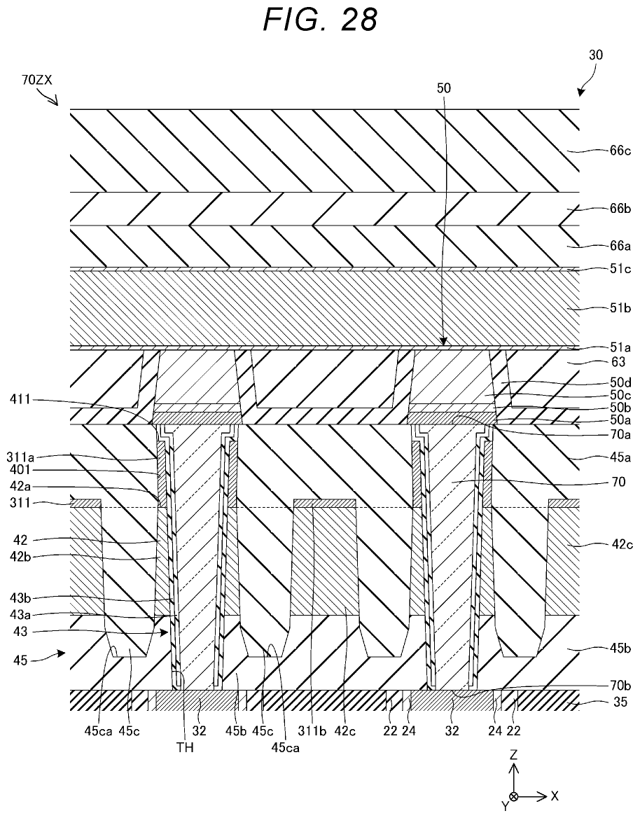

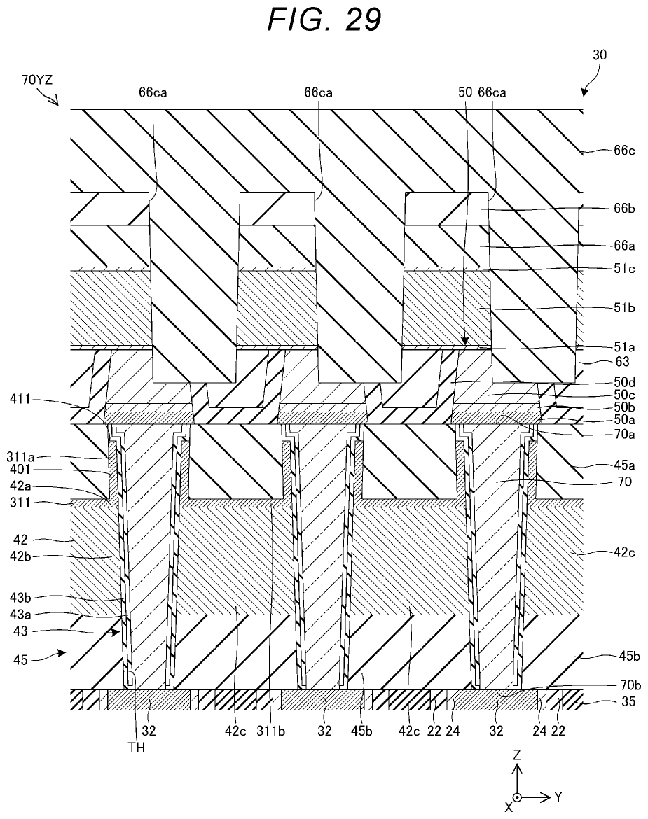

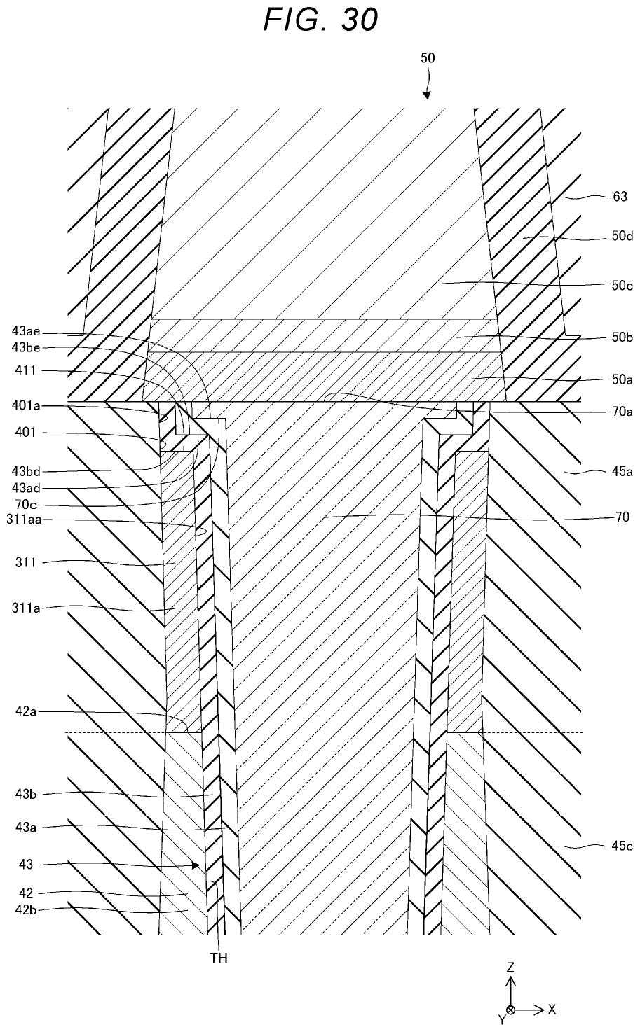

As illustrated in FIGS. 28 to 30, the semiconductor device 30 in the second example of the first embodiment is different from the semiconductor device 30 in the first example of the first embodiment illustrated in FIGS. 3 to 6 in that the step portion 411 is located further below.

The gate insulating film 43 is bent along the inner circumferential surface 311aa of the cylinder portion 311a, the step portion 411, and the inner wall 401a of the hole portion 401. Thus, the step portion 43bd and a step portion 43ae (which is an example of a “third step portion”) are respectively formed on the outer circumferential surface and the inner circumferential surface of the gate insulating film 43 (see FIG. 6).

More specifically, the insulating film 43b is bent along the inner circumferential surface 311aa of the cylinder portion 311a, the step portion 411, and the inner wall 401a of the hole portion 401. By the bending, the step portions 43bd and 43be are respectively formed on the outer circumferential surface and the inner circumferential surface of the insulating film 43b. The step portion 43bd comes into contact with the step portion 411.

The insulating film 43a is bent along the inner circumferential surface 311aa of the cylinder portion 311a, the step portion 411, and the inner wall 401a of the hole portion 401 with the insulating film 43b interposed therebetween. By the bending, the step portions 43ad and 43ae are respectively formed on the outer circumferential surface and the inner circumferential surface of the insulating film 43a. The step portion 43ad comes into contact with the step portion 43be of the insulating film 43b.

The outer circumferential surface of the oxide semiconductor layer 70 follows the inner circumferential surface 311aa of the cylinder portion 311a, the step portion 411, and the inner wall 401a of the hole portion 401 with the gate insulating film 43 interposed therebetween, so that a step portion 70c (which is an example of a “fourth step portion”) coming into contact with the step portion 43ae is formed in the oxide semiconductor layer 70.

A diameter of the oxide semiconductor layer 70 above the step portion 70c is greater than a diameter of the oxide semiconductor layer 70 below the step portion 70c. With such configuration, since a contact area between the upper electrode 50 and the upper end 70a of the oxide semiconductor layer 70 can be expanded, on-resistance can be reduced and the on-current Ion can be increased.

### Method of Manufacturing Semiconductor Device 30 According to Second Example of First Embodiment

According to a method of manufacturing the semiconductor device 30 in the second example of the first embodiment, as illustrated in FIG. 15, a removal amount of the metal spacer film 311 by etching is increased. Accordingly, the step portion 411 can be formed further below compared to the semiconductor device 30 in the first example of the first embodiment (see FIG. 6).

Hereinafter, a third example of the semiconductor device 30 in the first embodiment (hereinafter also referred to as the third example of the first embodiment) will be described.

### Third Example of First Embodiment

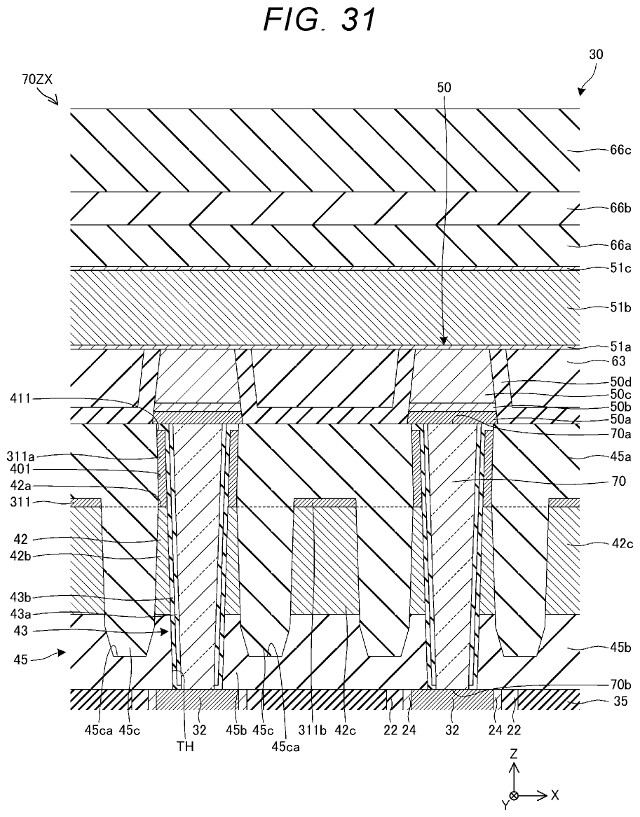

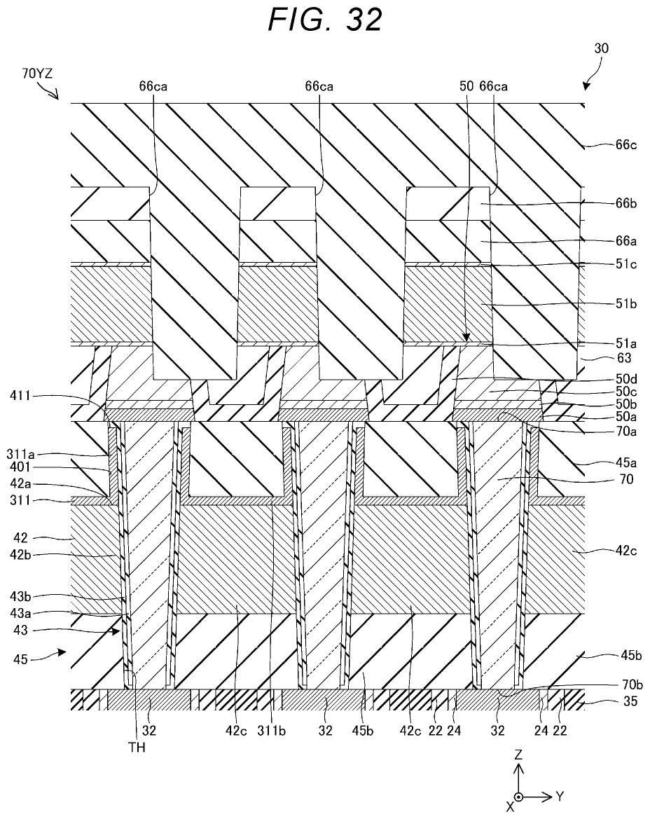

As illustrated in FIGS. 31 to 33, the semiconductor device 30 in the third example of the first embodiment is different from the semiconductor device 30 in the first example of the first embodiment illustrated in FIGS. 3 to 6 in that the step portion 411 is located further above.

The insulating film 43b is bent along the inner wall 311aa of the cylinder portion 311a and the step portion 411. By the bending, the step portion 43bd coming into contact with the step portion 411 is formed on the outer circumferential surface of the insulating film 43b. On the other hand, a step portion is not formed on the inner circumferential surface of the insulating film 43b.

The insulating film 43a is not bent. Therefore, a step portion is not formed on the outer circumferential surface and the inner circumferential surface of the insulating film 43a. That is, only the insulating film 43b spreads outward and is formed around between the upper end portion of the cylinder portion 311a and the upper electrode 50.

### Method of Manufacturing Semiconductor Device 30 According to Third Example of First Embodiment

According to a method of manufacturing the semiconductor device 30 in a third example of the first embodiment, as illustrated in FIG. 15, a removal amount of the metal spacer film 311 by etching is reduced. Accordingly, the step portion 411 can be formed further above compared to the semiconductor device 30 in the first example of the first embodiment (see FIG. 6).

Hereinafter, a fourth example of the semiconductor device 30 in the first embodiment (hereinafter also referred to as the fourth example of the first embodiment) will be described.

### Fourth Example of First Embodiment

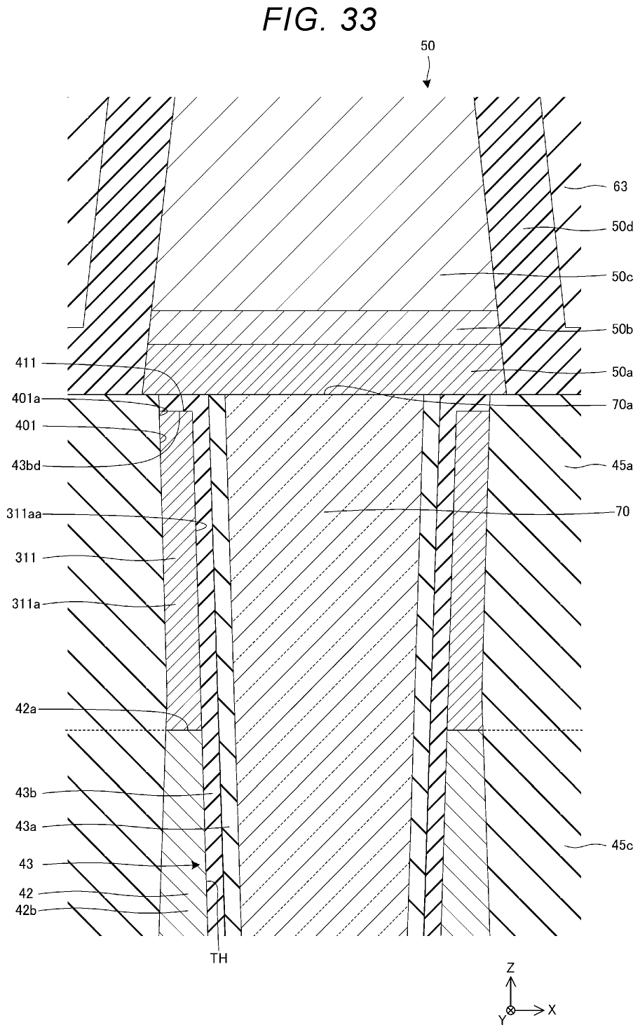

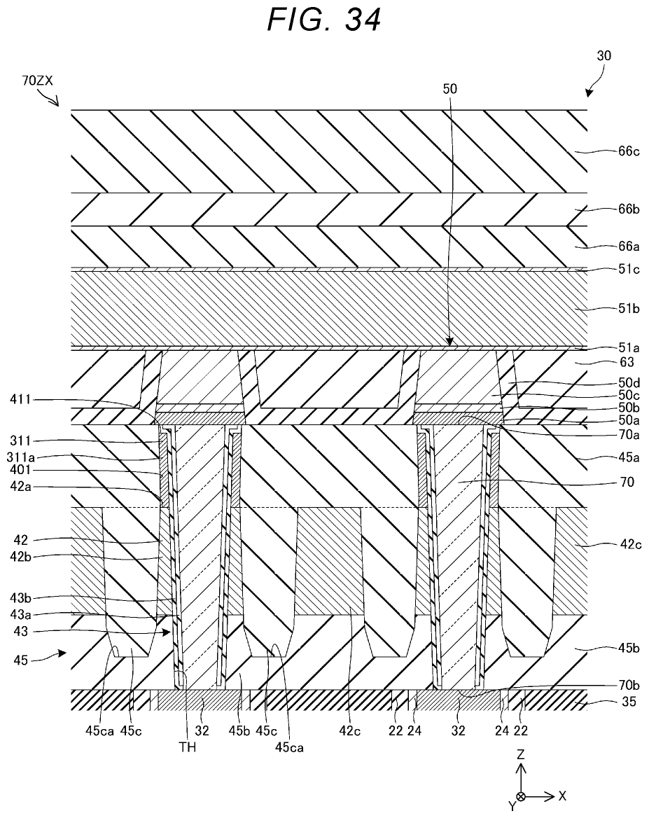

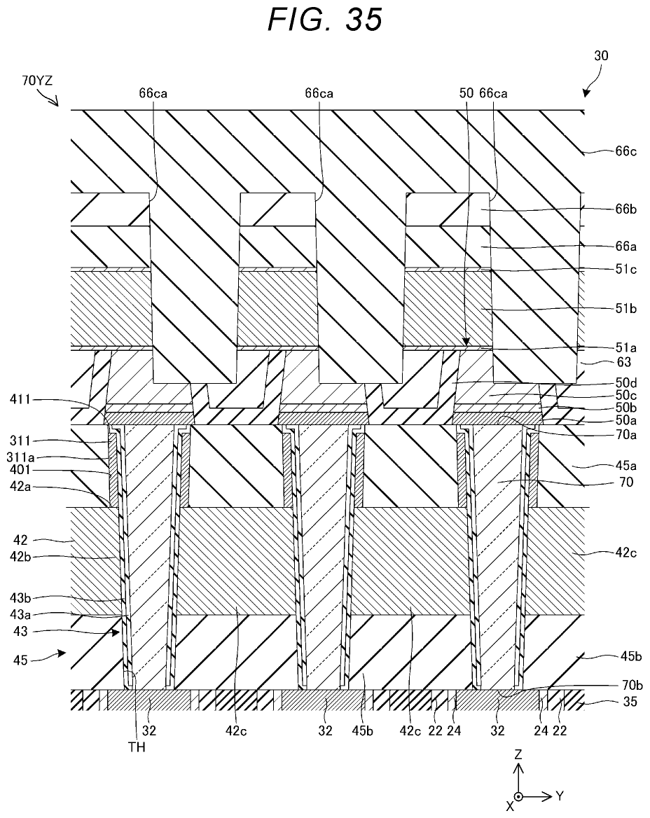

As illustrated in FIGS. 34 and 35, the semiconductor device 30 in the fourth example of the first embodiment is different from the semiconductor device 30 in the first example of the first embodiment illustrated in FIGS. 3 to 6 in that the plate portion 311b of the metal spacer film 311 is not provided above the connection portion 42c of the conductive layer 42.

The connection portion 42c of the conductive layer 42 comes into contact with the insulating film 45a (which is an example of a “second insulating film”) provided between the cylinder portions 311a. As such, with the configuration in which the conductive plate portion 311b is not provided, it is possible to inhibit a defect occurring at an unexpected location in a circuit in which the semiconductor device 30 is formed.

### Method of Manufacturing Semiconductor Device 30 according to Fourth Example of First Embodiment

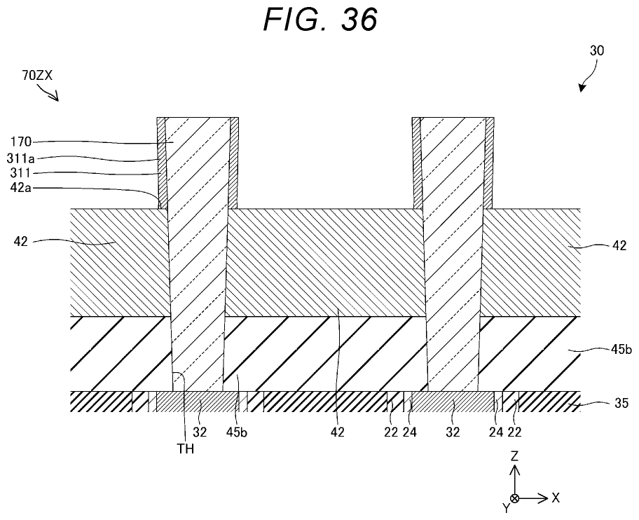

According to a method of manufacturing the semiconductor device 30 in a fourth example of the first embodiment, the metal spacer film 311 is formed above the semiconductor device 30 (see FIG. 11). Thereafter, as illustrated in FIG. 36, the metal spacer film 311 is removed by reactive ion etching except for the cylinder portion 311a.

As illustrated in FIG. 12, the groove portion 45ca penetrating until the insulating film 45b and extending to be substantially parallel to the Y axis is formed by etching.

Hereinafter, a fifth example of the semiconductor device 30 in the first embodiment (hereinafter also referred to as the fifth example of the first embodiment) will be described.

### Fifth Example of First Embodiment

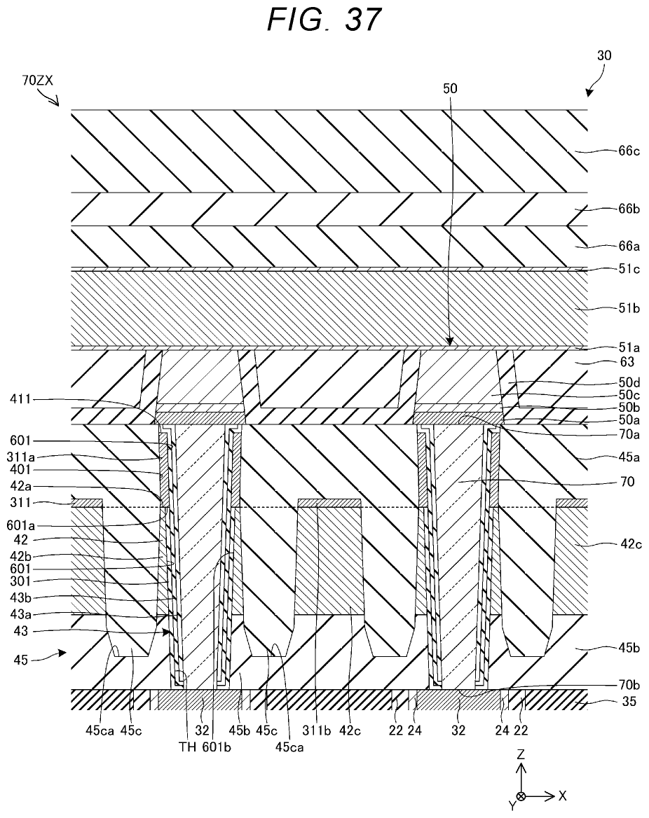

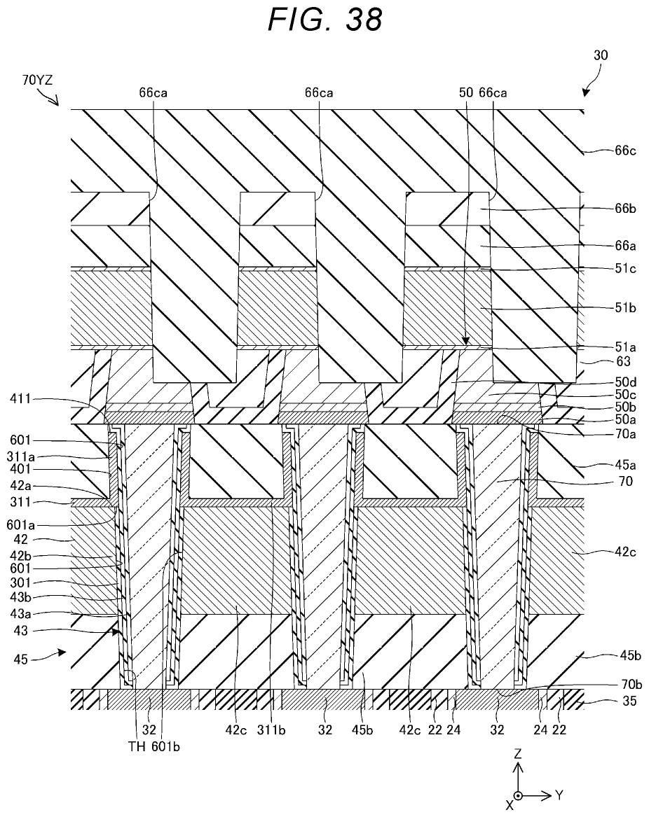

As illustrated in FIGS. 37 and 38, the semiconductor device 30 in the fifth example of the first embodiment is different from the semiconductor device 30 in the first example of the first embodiment illustrated in FIGS. 3 to 6 in that a liner film 301 covering a part of the lower portion of the gate insulating film 43 is further provided.

A hole portion 601 in which at least a part of the oxide semiconductor layer 70 is accommodated is formed by the enclosure portion 42b of the conductive layer 42 and the cylinder portion 311a of the metal spacer film 311. In the embodiment, the hole portion 601 accommodates a part of the oxide semiconductor layer 70.

A step surface 601a oriented in the −Z axis direction is formed on the inner wall 601b of the hole portion 601. The step surface 601a is located between the conductive layer 42 and the upper electrode 50. The step surface 601a is annular when viewed from the lower side.

In the embodiment, since an inner diameter of the lower end portion of the cylinder portion 311a is smaller than an upper inner diameter of the enclosure portion 42b, a portion at the center of the lower end surface of the cylinder portion 311a becomes the step surface 601a. The upper surface 42a of the conductive layer 42 and the step surface 601a are lined up.

The liner film 301 is located between at least the conductive layer 42 and the insulating film 45b, and the gate insulating film 43. The liner film 301 encloses the entire circumference of a lower part of the oxide semiconductor layer 70 from the outside of the gate insulating film 43. More specifically, the lower end portion of the liner film 301 comes into contact with the lower electrode 32. The upper end portion of the liner film 301 comes into contact with the step surface 601a of the hole portion 601, that is, the lower end surface of the cylinder portion 311a.

The liner film 301 contains, for example, at least one of elements including silicon, aluminum, zirconium, hafnium, lanthanum, titanium, and strontium, and at least one of elements including oxygen and nitrogen. In the embodiment, the liner 301 contains silicon nitride. The liner film 301 may contain silicon nitride, silicon oxynitride, aluminum oxide, aluminum nitride, zirconium oxide, hafnium oxide, ruthenium oxide, niobium oxide, yttrium oxide, tantalum oxide, vanadium oxide, magnesium oxide, lanthanum oxide, titanium oxide, or strontium oxide.

### Method of Manufacturing Semiconductor Device 30 according to Fifth Example of First Embodiment

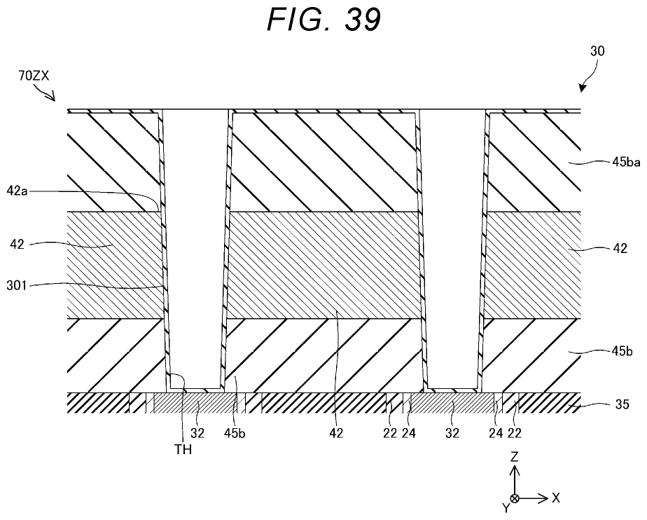

According to a method of manufacturing the semiconductor device 30 in the fifth example of the first embodiment, the transistor hole TH extending to be substantially parallel to the Z axis and penetrating through the insulating film 45ba, the conductive layer 42, and the insulating film 45b is formed, and then cleaned (see FIG. 7). As illustrated in FIG. 39, for example, the liner film 301 that has a thickness of 2 nm or more is formed above the semiconductor device 30 by atomic layer deposition. Accordingly, the inner wall of the transistor hole TH is covered with the liner film 301, so that the lower electrode 32 is not exposed.

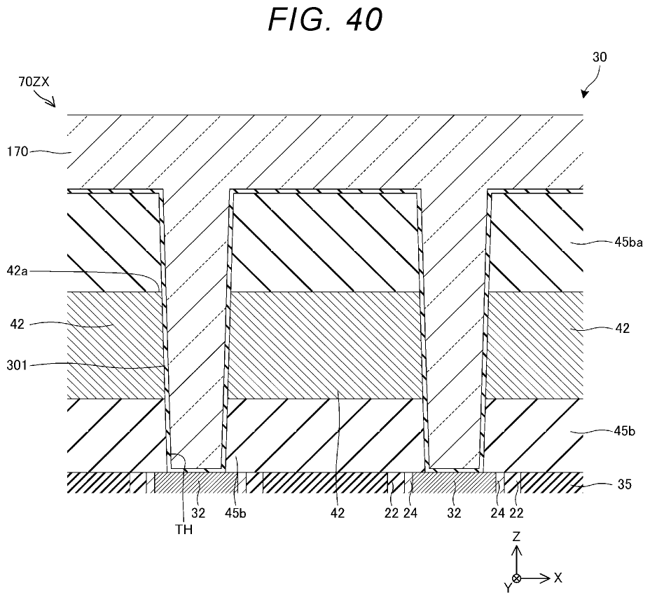

Subsequently, as illustrated in FIG. 40, the sacrifice amorphous silicon layer 170 is formed above the semiconductor device 30. Accordingly, the transistor hole TH is filled with the sacrifice amorphous silicon layer 170.

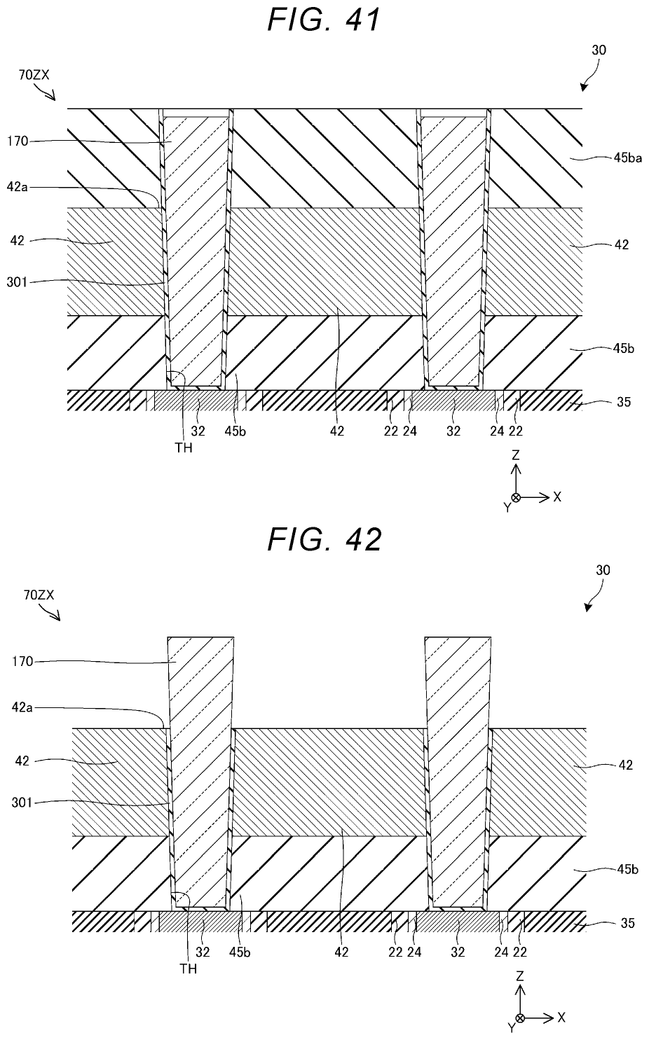

Subsequently, as illustrated in FIG. 41, the sacrifice amorphous silicon layer 170 is etched back, so that an upper part of the sacrifice amorphous silicon layer 170 is removed and the upper surface of the insulating film 45ba is exposed.

Subsequently, as illustrated in FIG. 42, the insulating film 45ba is removed by etching. The liner film 301 exposed above the conductive layer 42 is removed by etching. Accordingly, the upper surface 42a of the conductive layer 42 and the upper end portion of the liner film 301 are lined up.

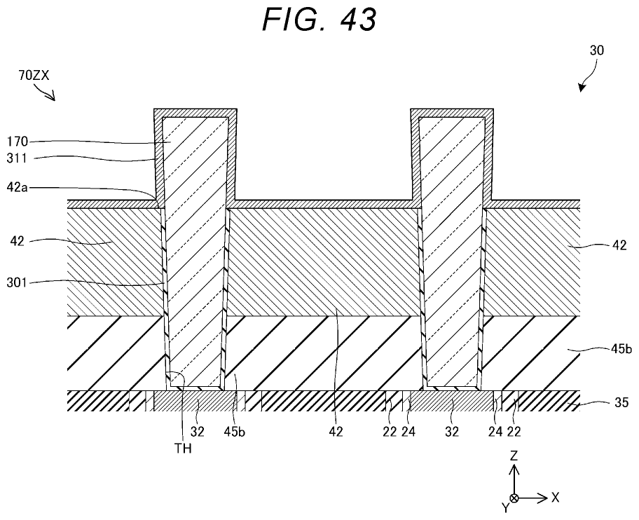

Subsequently, as illustrated in FIG. 43, the metal spacer film 311 is: formed above the semiconductor device 30. Accordingly, the sacrifice amorphous silicon layer 170 exposed above the conductive layer 42 and the upper surface 42a of the conductive layer 42 are covered with the metal spacer film 311.

### Second Embodiment

A semiconductor device 30B according to a second embodiment will be described. In the second and subsequent embodiments, description common to that of the first embodiment will be omitted and only differences will be described. In particular, similar operational effects in similar configurations will not be described successively in each embodiment.

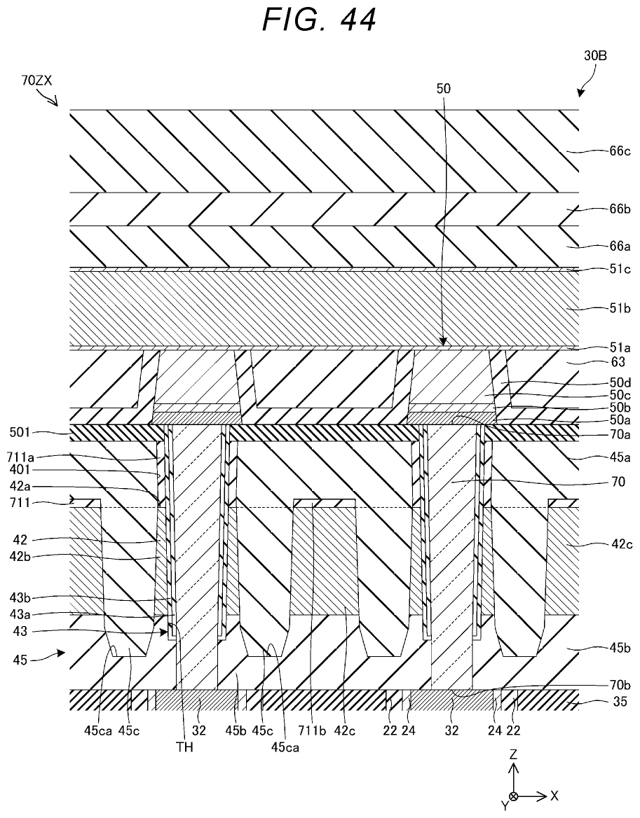

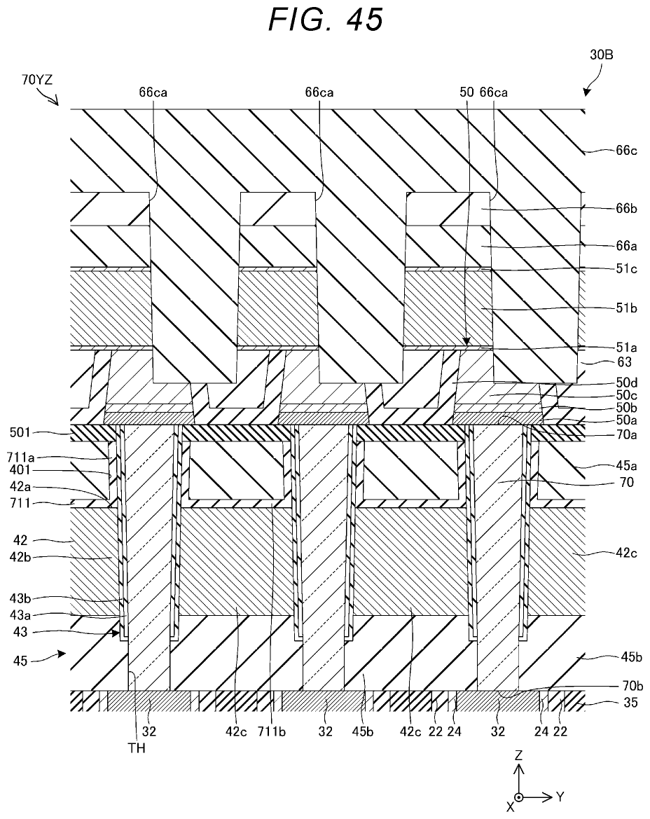

FIG. 44 illustrates the cross section 70ZX parallel to the ZX plane and a sectional view of the semiconductor device 30B when viewed on the cross section 70ZX in the oxide semiconductor layer 70. FIG. 45 illustrates the cross section 70YZ parallel to the YZ plane and a sectional view of the semiconductor device 30B when viewed on the cross section 70YZ in the oxide semiconductor layer 70.

As illustrated in FIGS. 44 and 45, the semiconductor device 30B according to the second embodiment includes a spacer film 711 instead of the metal spacer film 311 and further includes an insulating film 501 (which is an example of a “third insulating film”) compared to the semiconductor device 30 illustrated in FIGS. 3 to 6.

The insulating film 501 comes into contact with a part of the side surface of the gate insulating film 43 including an end portion in the +Z axis direction. In the embodiment, the insulating film 501 encloses a part of the gate insulating film 43 in the +Z axis direction.

More specifically, the insulating film 501 is a film extending to be substantially parallel to the XY plane and functions as a hard mask in manufacturing. The lower surface of the insulating film 501 comes into contact with the upper surface of the insulating film 45a (which is an example of a “fourth insulating film”). The upper surface of the insulating film 501 comes into contact with the lower surface of the upper electrode 50. The gate insulating film 43 and the oxide semiconductor layer 70 penetrate through the insulating film 501.

The insulating film 501 contains silicon oxide, silicon nitride, silicon oxynitride, aluminum oxide, hafnium oxide, zirconium oxide, ruthenium oxide, niobium oxide, yttrium oxide, tantalum oxide, vanadium oxide, or magnesium oxide.

An oxygen concentration of the insulating film 501 is less than an oxygen concentration of the gate insulating film 43. With such configuration, carriers of an extension region can be increased by dipoles generated by movement of oxygen from the gate insulating film 43 to the insulating film 501. Therefore, it is possible to increase the on-current Ion.

When the insulating film 501 is silicon oxide, the insulating film 501 has a higher density, a higher dielectric constant, or a higher Young's modulus than the insulating film 45a or the spacer film 711, and thus has higher CMP resistance or DRY resistance.

The spacer film 711 is an insulating film. Specifically, the spacer film 711 contains, for example, oxide of silicon. The spacer film 711 includes a plurality of cylinder portions 711a and at least one plate portion 711b.

The shape of the cylinder portion 711a of the spacer film 711 is similar to the shape of the cylinder portion 311a of the metal spacer film 311. The shape of the plate portion 711b of the spacer film 711 is similar to the shape of the plate portion 311b of the spacer film 311.

A lower end portion of the cylinder portion 711a is an annular surface coming into contact with the upper surface 42a of the conductive layer 42. An upper end portion of the cylinder portion 711a is an annular surface and comes into contact with the insulating film 501.

The gate insulating film 43 encloses a part of the oxide semiconductor layer 70 in the +Z axis direction. More specifically, the end portion of the gate insulating film 43 in the −Z axis direction is distant from the lower electrode 32. The end portion of the gate insulating film 43 in the −Z axis direction is located above the lower electrode 32 and is located below the conductive layer 42.

### Method of Manufacturing Semiconductor Device

Hereinafter, a method of manufacturing the semiconductor device 30B will be described as an example of a method of manufacturing a semiconductor device according to the second embodiment.

First, as illustrated in FIG. 46, the transistor hole TH is formed which extends to be substantially parallel to the Z axis and which penetrates halfway the insulating film 45b while passing the insulating film 45ba and the conductive layer 42, and then is cleaned. The insulating film 45b is exposed on the bottom of the transistor hole TH, but the lower electrode 32 is not exposed.

Subsequently, as illustrated in FIG. 47, the sacrifice amorphous silicon layer 170 is formed above the semiconductor device 30B. Accordingly, the transistor hole TH is filled with the sacrifice amorphous silicon layer 170.

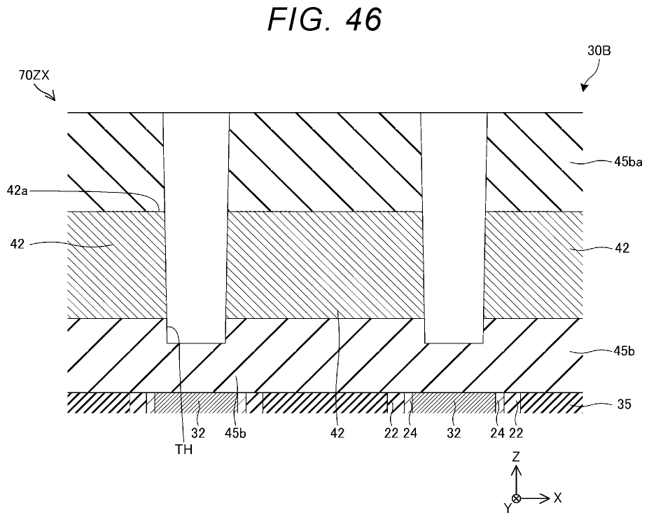

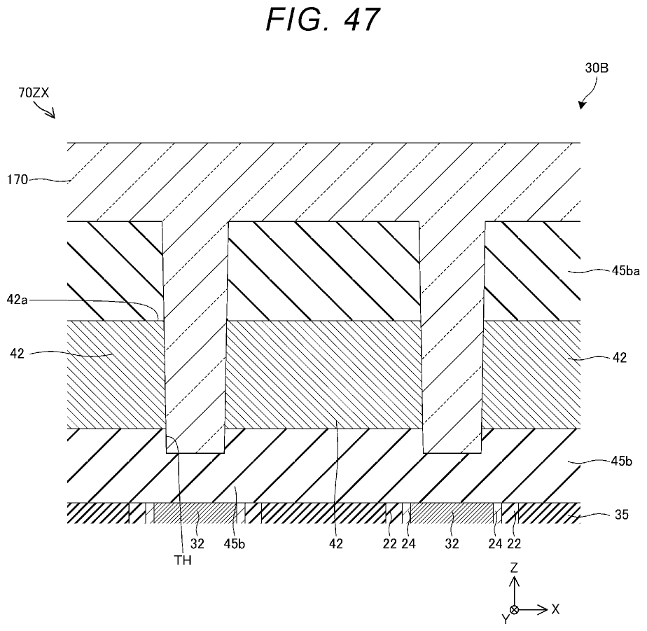

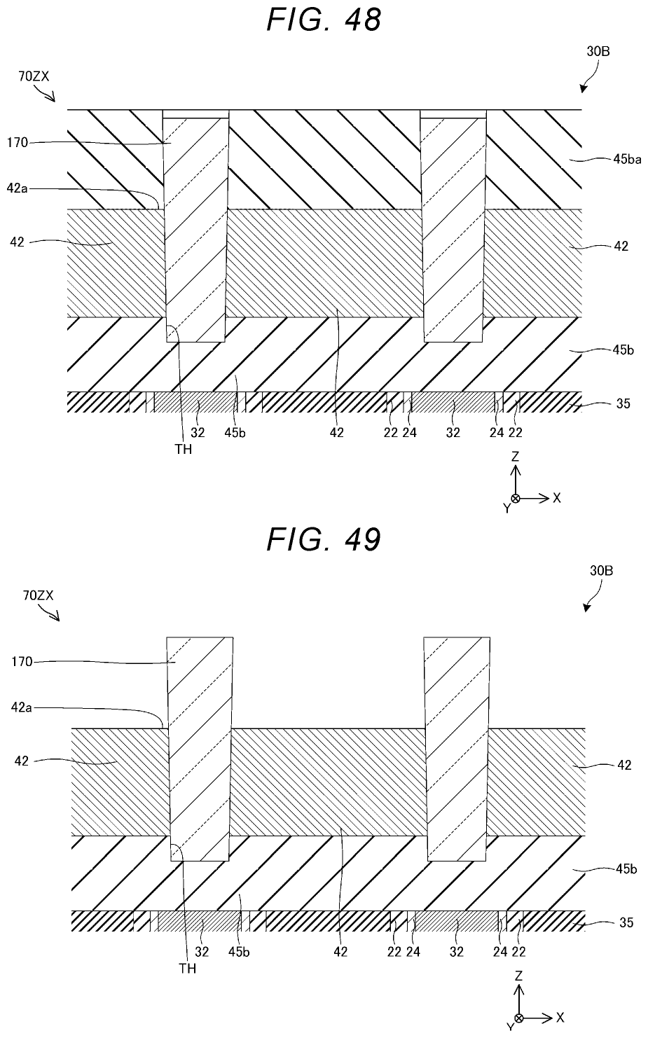

Subsequently, as illustrated in FIG. 48, by etching back the sacrifice amorphous silicon layer 170, an upper part of the sacrifice amorphous silicon layer 170 is removed and the upper surface of the insulating film 45ba is exposed.

Subsequently, as illustrated in FIG. 49, the insulating film 45ba is removed by etching.

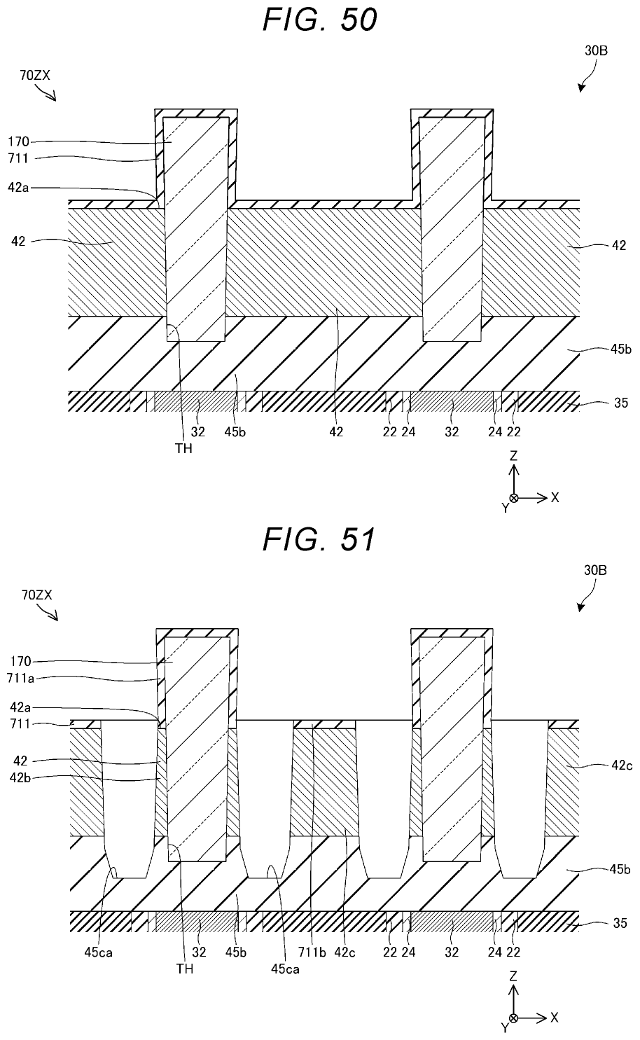

Subsequently, as illustrated in FIG. 50, the spacer film 711 is formed above the semiconductor device 30B. Accordingly, the sacrifice amorphous silicon layer 170 exposed above the conductive layer 42 and the upper surface 42a of the conductive layer 42 are covered with the spacer film 711.

Subsequently, as illustrated in FIG. 51, film forming, resist coating, exposure, development, separation, and the like are performed on the surface of the semiconductor device 30B by a lithographic method to form a mask. Thereafter, in the semiconductor device 30B, the groove portion 45ca penetrating until the insulating film 45b and extending to be substantially parallel to the Y axis is formed by etching. Accordingly, the spacer film 711 is separated into the cylinder portion 711a and the plate portion 711b. The conductive layers 42 extend to be substantially parallel to the Y axis and are separated into a plurality of electrodes repeatedly provided in the +X axis direction. The electrodes correspond to the word lines WL (see FIG. 1).

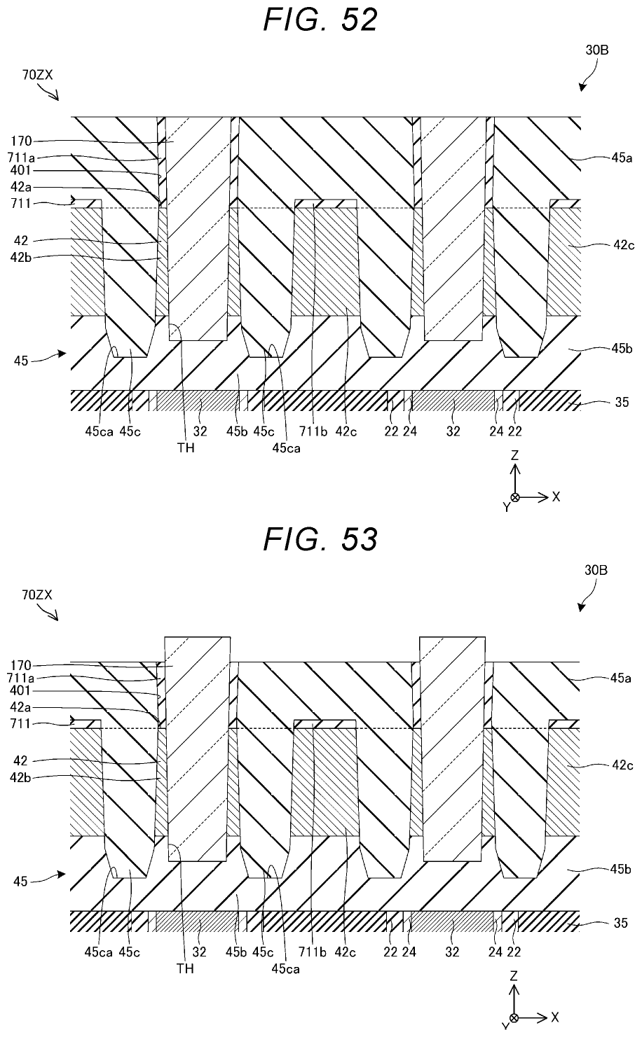

Subsequently, as illustrated in FIG. 52, the insulating films 45c and 45a are integrally formed above the semiconductor device 30B. Then, chemical mechanical polishing is performed on the upper surface of the semiconductor device 30B, so that the upper surface of the sacrifice amorphous silicon layer 170 is exposed from the insulating film 45a.

Subsequently, as illustrated in FIG. 53, an upper part of the insulating film 45a and an upper part of the cylinder portion 711a are removed by etching, so that an upper part of the sacrifice amorphous silicon layer 170 is exposed from the insulating film 45a and the cylinder portion 711a.

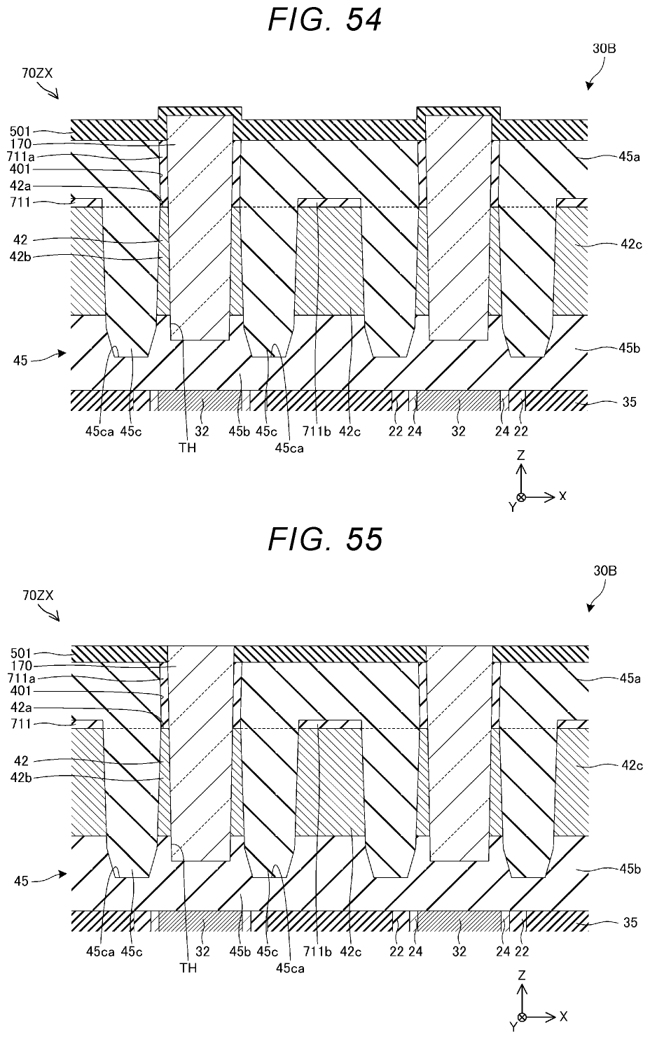

Subsequently, as illustrated in FIG. 54, the insulating film 501 is formed above the semiconductor device 30B.

Subsequently, as illustrated in FIG. 55, chemical mechanical polishing is performed on the upper surface of the semiconductor device 30B, so that the upper surface of the sacrifice amorphous silicon layer 170 is exposed from the insulating film 501.

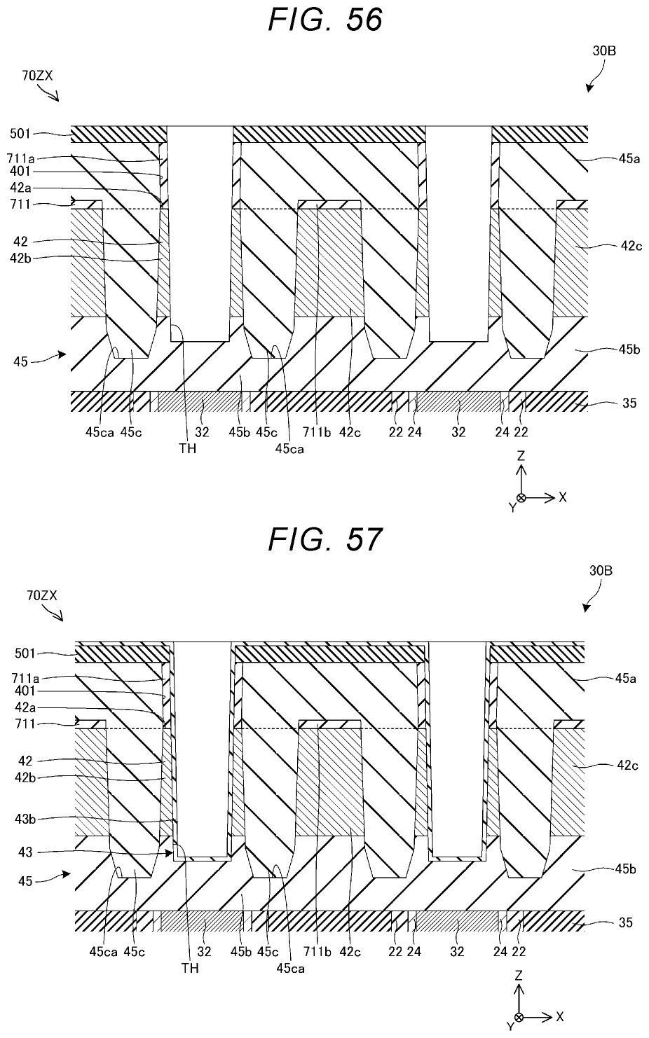

Subsequently, as illustrated in FIG. 56, the upper portion of the semiconductor device 30B is etched back by wet etching, so that the sacrifice amorphous silicon layer 170 is removed. The insulating film 45b is exposed on the bottom of the transistor hole TH.

Subsequently, as illustrated in FIG. 57, the insulating film 43b is formed above the semiconductor device 30B.

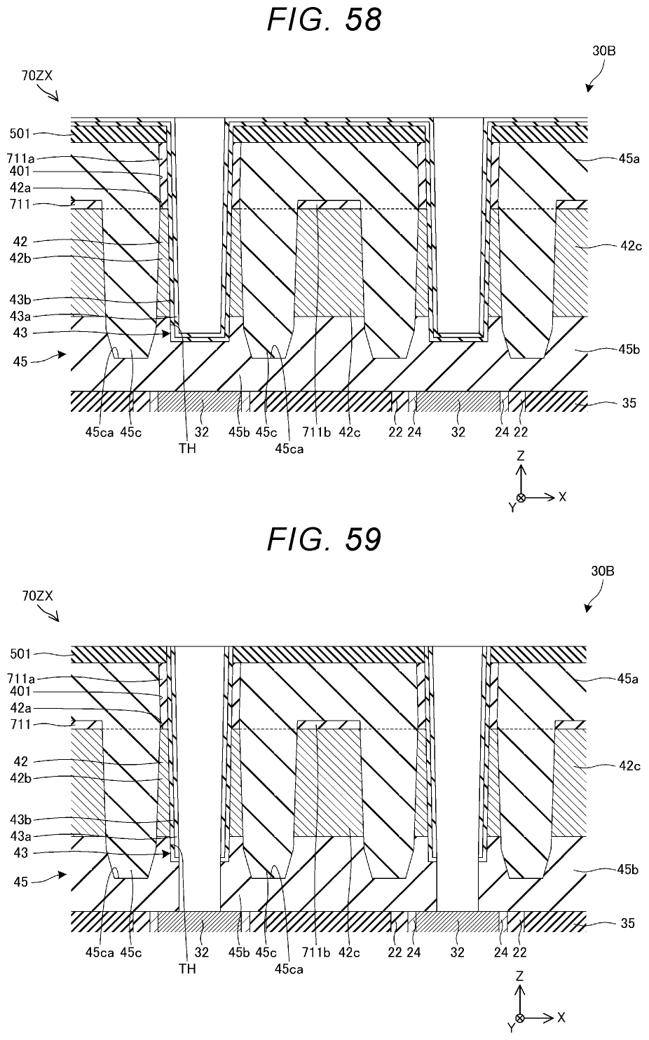

Subsequently, as illustrated in FIG. 58, the insulating film 43a is formed above the semiconductor device 30B.

Subsequently, as illustrated in FIG. 59, an upper portion of the semiconductor device 30B is etched back by reactive ion etching, so that the insulating film 501 is exposed and the lower electrode 32 is exposed on the bottom of the transistor hole TH.

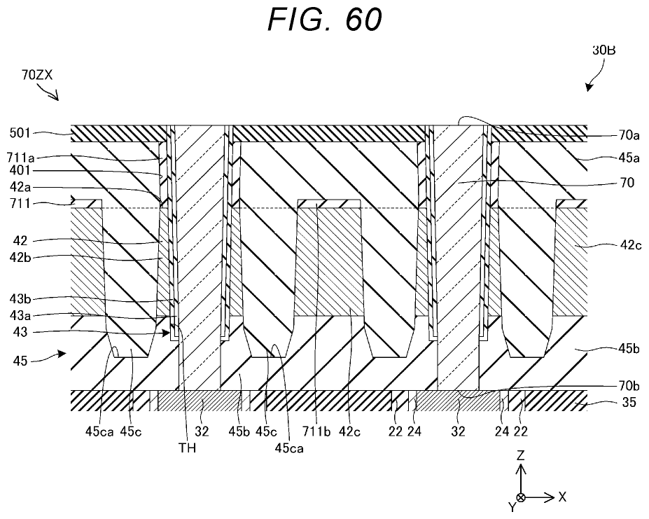

Subsequently, as illustrated in FIG. 60, the oxide semiconductor layer 70 is formed in the transistor hole TH. Then, chemical mechanical polishing is performed on the upper surface of the semiconductor device 30B.

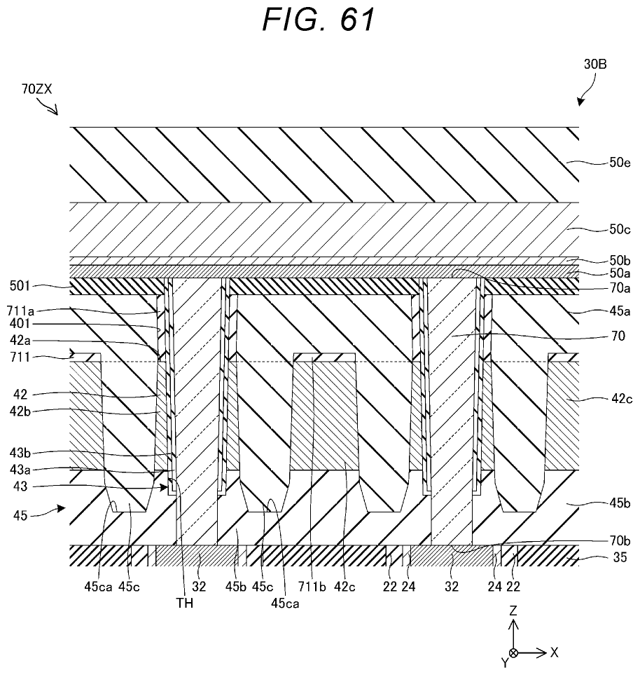

Subsequently, as illustrated in FIG. 61, the metal oxide layer 50a, the barrier metal layer 50b, and the metal film 50c are formed from the lower side to the upper side on the upper surface of the semiconductor device 30B. Then, for example, the LPHM film 50e containing oxide of silicon is formed above the metal film 50c.

### Advantages

If the insulating film 501 is not formed, when an upper portion of the semiconductor device 30B is etched back by wet etching to remove the sacrifice amorphous silicon layer 170, an upper part of the insulating film 45a is also removed in some cases.

When a time of the wet etching is shortened to control a removal amount of the insulating film 45a, the sacrifice amorphous silicon layer 170 cannot be sufficiently removed in some cases. As such, the removal of the sacrifice amorphous silicon layer 170 and damage control of the insulating film 45a by wet etching have a trade-off relationship.

In the embodiment, however, as illustrated in FIG. 56, even when the time of the wet etching is lengthened to the degree that the sacrifice amorphous silicon layer 170 can be removed in a configuration in which the insulating film 501 functioning as a hard mask is provided above the insulating film 45a, damage of the insulating film 45a by wet etching can be controlled by the insulating film 501.

As illustrated in FIG. 59, when the upper portion of the semiconductor device 30B is etched back by reactive ion etching, the insulating film 501 can prevent the circumference of the transistor hole TH from being damaged. Accordingly, it is possible to increase the diameter of the upper portion of the transistor hole TH and prevent the transistor hole TH from being opened in a wrapper shape.

(a) The first insulating film includes the first film with a cylindrical shape and the second film with a cylindrical shape provided between the first film and the oxide semiconductor.

The first film is bent along the inner circumferential surface of the cylindrical portion, the first step portion, and the inner wall of the hole portion to form the second step portion and the fifth step portion on the outer circumferential surface and the inner circumferential surface of the first film, respectively.

(b) The first insulating film includes the first film with a cylindrical shape and the second film with a cylindrical shape provided between the first film and the oxide semiconductor.

The first film is bent along the inner circumferential surface of the cylindrical portion and the first step portion to form the second step portion on the outer circumferential surface of the first film.

A step is not formed on the inner circumferential surface of the first film.

(c) The second film is bent along the inner circumferential surface of the cylindrical portion and the first step portion with the first film interposed therebetween to form the sixth step portion on the outer circumferential surface of the second film.

A step is not formed on the inner circumferential surface of the second film.

(d) A step is not formed on the second film.

(e) The metal film contains, for example, titanium, tantalum, tungsten, platinum, ruthenium, nickel, cobalt, palladium, gold or copper, or nitride of titanium, tantalum, and tungsten.

(f) The third insulating film contains silicon oxide, silicon nitride, silicon oxynitride, aluminum oxide, hafnium oxide, zirconium oxide, ruthenium oxide, niobium oxide, yttrium oxide, tantalum oxide, vanadium oxide, or magnesium oxide.

(g) The second electrode contains at least one of elements including indium, tin, zinc, cadmium, gold, silver, platinum, lead, copper, nickel, tungsten, and iron.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first oxide semiconductor including a first end and a second end, the first oxide semiconductor extending in a first direction oriented from the second end to the first end;
a first electrode in contact with the first end of the first oxide semiconductor;
a second electrode in contact with the second end of the first oxide semiconductor;
a first metal film arranged to enclose the first oxide semiconductor with a first insulating film interposed therebetween in a part between the first end and the second end of the first oxide semiconductor;
a second metal film including a first cylindrical portion in contact with the first metal film in the first direction side, the second metal film encloses the first oxide semiconductor with the first insulating film interposed therebetween;
a second oxide semiconductor including a third end and a fourth end, the second oxide semiconductor extending in the first direction;
a third electrode in contact with the third end of the second oxide semiconductor;
a fourth electrode in contact with the fourth end of the second oxide semiconductor;
the first metal film arranged to enclose the second oxide semiconductor with a second insulating film interposed therebetween in a part between the third end and the fourth end of the second oxide semiconductor;
the second metal film including a second cylindrical portion that contacts the first metal film in the first direction side, the second metal film encloses the second oxide semiconductor with the second insulating film interposed therebetween; and
a third insulating film disposed between the first cylindrical portion and the second cylindrical portion.

2. The semiconductor device according to claim 1, wherein
the first and second oxide semiconductors are disposed along a second direction intersecting the first direction,
the first metal film extends in the second direction, and the first metal film includes:
a first enclosure portion arranged to enclose the first oxide semiconductor with the first insulating film interposed therebetween,
a second enclosure portion arranged to enclose the second oxide semiconductor with the second insulating film interposed therebetween, and
a connection portion arranged to connect the first enclosure portion to the second enclosure portion, and
the second metal film is disposed (a) above the connection portion and (b) between the connection portion and the third insulating film.

3. The semiconductor device according to claim 1, further comprising:
a third insulating film disposed on the first metal film in the first direction side and including a first hole portion through which the first oxide semiconductor penetrates, wherein
the first cylindrical portion is inserted into a part of the first hole portion in a direction side opposite to the first direction, and
a first step portion is formed by the first hole portion and the first cylindrical portion.

4. The semiconductor device according to claim 3, wherein
The first insulating film has a first cylindrical shape, and
the first insulating film is bent along an inner circumferential surface of the first cylindrical portion and the first step portion to form a second step portion contacting the first step portion on an outer circumferential surface of the first insulating film.

5. The semiconductor device according to claim 4, wherein a step is not formed on an inner circumferential surface of the first insulating film.

6. The semiconductor device according to claim 4, wherein the first insulating film is further bent along an inner wall of the first hole portion on the inner circumferential surface of the first insulating film to form a third step portion.

7. The semiconductor device according to claim 6, wherein
the first oxide semiconductor has a pillar shape, and
an outer circumferential surface of the first oxide semiconductor follows the inner circumferential surface of the first cylindrical portion, the first step portion, and the inner wall of the first hole portion with the first insulating film interposed therebetween to form a fourth step portion contacting with the third step portion in the first oxide semiconductor.

8. The semiconductor device according to claim 1, wherein a distance between the first electrode and the first cylindrical portion is 4 nm or more and 30 nm or less.

9. A semiconductor device comprising:
an oxide semiconductor including a first end and a second end, the oxide semiconductor extending in a first direction oriented from the second end to the first end;
a first electrode arranged to contact the first end of the oxide semiconductor;
a second electrode configured to contact the second end of the oxide semiconductor;
a first insulating film arranged to enclose at least a part of the oxide semiconductor in the first direction side;
a gate electrode arranged to enclose the oxide semiconductor with the first insulating film interposed therebetween between the first and second ends of the oxide semiconductor;
a third insulating film arranged to contact a part of a side surface of the first insulating film including an end portion in the first direction side; and
a fourth insulating film arranged to contact the third insulating film in a direction side opposite to the first direction, wherein
a material of the third insulating film is different from a material of the fourth insulating film.

10. The semiconductor device according to claim 9, wherein the third insulating film encloses a part of the first insulating film in the first direction side.

11. The semiconductor device according to claim 9, wherein the third insulating film contacts the first electrode.

12. The semiconductor device according to claim 9, wherein an oxygen concentration of the third insulating film is less than an oxygen concentration of the first insulating film.

13. A semiconductor device comprising:
an oxide semiconductor including a first end and a second end, the oxide semiconductor extending in a first direction oriented from the second end to the first end;
a first electrode arranged to contact the first end of the oxide semiconductor;
a second electrode arranged to contact the second end of the oxide semiconductor;
a first insulating film arranged to enclose at least a part of the oxide semiconductor in the first direction side; and
a gate electrode arranged to enclose the oxide semiconductor with the first insulating film interposed therebetween between the: first and second ends of the oxide semiconductor, wherein
the second electrode is distant from an end portion of the first insulating film in a direction side opposite to the first direction.

14. The semiconductor device according to claim 1 wherein
the semiconductor device includes a plurality of the oxide semiconductors provided along a second direction intersecting the first direction,
the gate electrode includes a plurality of enclosure portions extending in the second direction and enclosing the plurality of oxide semiconductors with the first insulating film interposed therebetween, and at least one connection portion connecting the enclosure portions to each other, and
a width of the connection portion is narrower than a width of the enclosure portion.

15. The semiconductor device according to claim 1, wherein
a second hole portion through which the oxide semiconductor penetrates is formed in the gate electrode, and
the gate electrode is formed to be self-aligned with the second hole portion.

16. A semiconductor memory device comprising:
the semiconductor device according to claim 1;
a first capacity electrode connected to the first electrode or the second electrode;
a second capacity electrode facing the first capacitor electrode; and
a dielectric film disposed between the first and second capacitor electrodes.

17. The semiconductor device according to claim 9, wherein the third and fourth insulating films contain oxygen and silicon, and a density or a Young's modulus of the third insulating film is higher than a density or a Young's modulus of the fourth insulating film.

18. The semiconductor device according to claim 9, wherein the third and fourth insulating films contain oxygen and silicon, and a dielectric constant of the third insulating film is higher than a dielectric constant of the fourth insulating film.

19. The semiconductor device according to claim 9, wherein the third insulating film is adjacent to the oxide semiconductor in a second direction intersecting the first direction and contacts the first insulating film.

20. The semiconductor device according to claim 9, wherein the first electrode contacts the third insulating film in the first direction.
